(19) United States
(12) Patent Application Publication
(10) Pub. No.: US 2026/0172008 A1
(43) Pub. Date: Jun. 18, 2026

(54) SUPERCONDUCTING SQUARE PULSE WAVEFORM GENERATORS

(71) Applicant: International Business Machines Corporation, Armonk, NY (US)

(72) Inventors: Matthew Beck, Danbury, CT (US); Ted Thorbeck, Elmsford, NY (US); Joseph Robert Suttle, Chappaqua, NY (US); Santino Carnevale, Stamford, CT (US); Joseph Finley, Rye Brook, NY (US)

(21) Appl. No.: 18/980,065

(22) Filed: Dec. 13, 2024

(51) Int. Cl. H03K 3/38; G06N 10/40

(52) U.S. Cl. CPC H03K 3/38; G06N 10/40

(57) ABSTRACT

A device comprises a superconducting square pulse waveform generator which comprises a self-oscillating circuit that is configured to generate a continuous sequence of square current pulses in response to a single flux quantum (SFQ) pulse applied to an input port of the superconducting square pulse waveform generator. The self-oscillating circuit is responsive to a first direct current (DC) control signal to tune a pulse period of the continuous sequence of square current pulses, and responsive to a second DC control signal to tune a pulse width of the square current pulses.

### BACKGROUND

This disclosure relates generally to quantum computing and, in particular, to techniques for generating control signals for operating quantum circuit components and devices in superconducting quantum computing systems. A quantum computing system can be implemented using superconducting circuit quantum electrodynamics (cQED) architectures that are constructed using quantum circuit components such as, e.g., superconducting quantum bits and other types of superconducting quantum devices and circuitry. In general, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures.

The cryogenic hardware that is utilized to implement a quantum computer with superconducting qubits requires a variety of microwave components including, e.g., qubit couplers, microwave filters, quantum limited amplifiers, Josephson parametric frequency converters and mixers, isolators, switches, and other microwave components that are implemented in qubit control and readout signal paths etc., which are controlled using various control signals, such as radio frequency (RF) control pulses, RF pump signals, flux-bias control pulses, etc. The cryogenic hardware is disposed on a base stage (e.g., millikelvin (mK) stage) of a dilution refrigerator (in a cryogenic environment), wherein the control signals (e.g., RF control pulses, RF pump signals, flux-bias control pulses, etc.) are typically generated by electronics operating in a non-cryogenic environment (e.g., room temperature, 300 K) are transmitted via high bandwidth lines that extend from the room temperature electronics through the dilution refrigerator to the cryogenic hardware in the base stage. As such, these control signals must propagate over relatively long distances of dispersive cables, which leads to distortions in the profile of such control signals.

### SUMMARY

Exemplary embodiments of the disclosure include superconducting square pulse waveform generators and techniques for generating continuous square-shaped current pulse waveforms which are utilized, for example, to operate superconducting quantum devices and circuits of a quantum computing system.

An exemplary embodiment includes a device which comprises a superconducting square pulse waveform generator which comprises a self-oscillating circuit that is configured to generate a continuous sequence of square current pulses, in response to a single flux quantum (SFQ) pulse applied to an input port of the superconducting square pulse waveform generator. The self-oscillating circuit is responsive to a first direct current (DC) control signal to tune a pulse period of the continuous sequence of square current pulses, and responsive to a second DC control signal to tune a pulse width of the square current pulses.

Another exemplary embodiment includes a device which comprises a superconducting square pulse waveform generator which comprises a first superconducting sub-circuit and a second superconducting sub-circuit which comprises a quantizing inductor. The first superconducting sub-circuit is configured to receive an SFQ pulse applied to an input port of the superconducting square pulse waveform generator, and propagate the SFQ pulse around the first superconducting sub-circuit to periodically inject (i) a first SFQ pulse into the second superconducting sub-circuit to cause a first circulating current to flow in a first direction through the quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

Another exemplary embodiment includes a method which comprises: receiving, by a superconducting square pulse waveform generator, a single flux quantum (SFQ) pulse; and generating, by the superconducting square pulse waveform generator, a continuous sequence of square current pulses in response to the SFQ pulse; wherein generating the continuous sequence of square current pulses comprises propagating the received SFQ pulse around a first superconducting sub-circuit of the superconducting square pulse waveform generator to periodically inject (i) a first SFQ pulse into a second superconducting sub-circuit of the superconducting square pulse waveform generator to cause a first circulating current to flow in a first direction through a quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

Other embodiments will be described in the following detailed description of exemplary embodiments, which is to be read in conjunction with the accompanying figures.

### BRIEF DESCRIPTION OF THE DRAWINGS

FIG. 1A schematically illustrates a device which comprises a superconducting square pulse waveform generator, according to an exemplary embodiment of the disclosure.

FIG. 1B schematically illustrates a device which comprises a superconducting square pulse waveform generator, according to another exemplary embodiment of the disclosure.

FIG. 2 schematically illustrates a superconducting square pulse waveform generator, according to an exemplary embodiment of the disclosure.

FIGS. 3A, 3B, 3C, 3D, 3E, 3F, 3G, 3H, 3I, 3J, 3K, 3L, 3M, and 3N schematically illustrate an exemplary mode of operation of a superconducting square pulse waveform generator, according to an exemplary embodiment of the disclosure.

FIGS. 4A, 4B, and 4C illustrate simulated square pulse waveforms which can be generated using a superconducting square pulse waveform generator, according to exemplary embodiments of the disclosure.

FIG. 5 schematically illustrates a superconducting square pulse waveform generator, according to another exemplary embodiment of the disclosure.

FIG. 6 schematically illustrates a feeding Josephson transmission line which can be implemented in a superconducting square pulse waveform generator, according to an exemplary embodiment of the disclosure.

FIG. 7 schematically illustrates a superconducting square pulse waveform generator, according to another exemplary embodiment of the disclosure.

FIG. 8 schematically illustrates a single flux quantum pulse multiplier which can be implemented in a superconducting square pulse waveform generator, according to an exemplary embodiment of the disclosure.

FIG. 9 schematically illustrates a Josephson transmission line which can be implemented in a superconducting square pulse waveform generator, according to an exemplary embodiment of the disclosure.

FIG. 10 schematically illustrates a single flux quantum pulse splitter which can be implemented in a superconducting square pulse waveform generator, according to an exemplary embodiment of the disclosure.

FIG. 11 schematically illustrates a confluence buffer circuit which can be implemented in a superconducting square pulse waveform generator, according to an exemplary embodiment of the disclosure.

FIG. 12 schematically illustrates a quantum computing system which comprises superconducting square pulse waveform generator circuitry, according to an exemplary embodiment of the disclosure.

FIG. 13 schematically illustrates an exemplary architecture of a computing environment for hosting a quantum computing platform, according to an exemplary embodiment of the disclosure.

### DETAILED DESCRIPTION

Exemplary embodiments of the disclosure will now be described in further detail with regard to superconducting square pulse waveform generators and techniques for generating high-frequency square pulse waveforms for operating quantum circuit components and devices of a quantum computing system. The exemplary superconducting square pulse waveform generators are implemented using superconducting single flux quantum (SFQ) circuitry which is configured to operate in cryogenic environments (e.g., in a cryostat or dilution refrigerator) to generate square-shaped current pulse waveforms using SFQ pulses and associated SFQ circuitry, such as direct current (DC)-powered SFQ circuitry such as rapid single flux quantum (RSFQ) circuitry and energy-efficient rapid single flux quantum (ERSFQ) circuitry.

As is known in the art, an SFQ pulse (also referred to as a superconducting magnetic single flux quantum pulse) is a voltage pulse whose time integral is equal to a discrete amount of magnetic flux, i.e., a superconducting magnetic flux quantum, referred to herein as a “fluxon.” More specifically, an SFQ pulse comprises a voltage pulse having a small magnitude (e.g., 1 millivolt (mV)) and a short duration (e.g., 2 picoseconds), wherein an area of the SFQ pulse (i.e., integral of voltage over time) is equal to one superconducting magnetic flux quantum Φ₀ (or one fluxon), where Φ₀=h/(2e)≈2.07×10⁻¹⁵ Weber (volt-seconds), where h is Planck's constant, and e denotes a magnitude of electron charge. As is known in the art, the superconducting magnetic flux quantum Φ₀ is a fundamental unit of magnetic flux which represents a quantization of magnetic flux threading a superconducting loop. In this regard, an SFQ pulse is any voltage pulse having a magnitude (in millivolts) and duration (picoseconds) such that the integral of the magnitude (voltage) over the duration (time) of the SFQ pulse (i.e., quantized area of SFQ pulse) is substantially equal to Φ₀=2.07 millivolt-picosecond (or 2.07 mA-pH), which equates to one superconducting magnetic flux quantum (or one fluxon).

An exemplary embodiment includes a device which comprises a superconducting square pulse waveform generator which comprises a self-oscillating circuit that is configured to generate a continuous sequence of square current pulses, in response to an SFQ pulse applied to an input port of the superconducting square pulse waveform generator. The self-oscillating circuit is responsive to a first direct current (DC) control signal to tune a pulse period of the continuous sequence of square current pulses, and responsive to a second DC control signal to tune a pulse width of the square current pulses.

In another exemplary embodiment, which may be combined with one or more of the embodiments of the preceding paragraphs, the self-oscillating circuit comprises a first superconducting sub-circuit, and a second superconducting sub-circuit which comprises a quantizing inductor. The first superconducting sub-circuit is configured to receive the SFQ pulse applied to the input port of the superconducting square pulse waveform generator, and propagate the SFQ pulse around the first superconducting sub-circuit to periodically inject (i) a first SFQ pulse into the second superconducting sub-circuit to cause a first circulating current to flow in a first direction through the quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

In another exemplary embodiment, which may be combined with one or more of the embodiments of the preceding paragraphs, the first superconducting sub-circuit comprises a first Josephson transmission line having a tunable propagation delay that is tuned based on the first DC control signal to tune the pulse period of the continuous sequence of square current pulses, and the second superconducting sub-circuit comprises a second Josephson transmission line having a tunable propagation delay that is adjusted based on the second DC control signal to tune the pulse width of the square current pulses.

In another exemplary embodiment, which may be combined with one or more of the embodiments of the preceding paragraphs, the first DC control signal comprises a first DC bias current that is applied to the first Josephson transmission line; and the second DC control signal comprises a second DC bias current that is applied to the second Josephson transmission line.

In another exemplary embodiment, which may be combined with one or more of the embodiments of the preceding paragraphs, the first superconducting sub-circuit comprises a first SFQ pulse splitter, and a second SFQ splitter. The first SFQ pulse splitter is configured to inject the first SFQ pulse into the second superconducting sub-circuit to cause the first circulating current to flow in the first direction through the quantizing inductor. The second SFQ pulse splitter is configured to inject the second SFQ pulse into the second superconducting sub-circuit to cause the second circulating current to flow through the quantizing inductor in the second direction.

In another exemplary embodiment, which may be combined with one or more of the embodiments of the preceding paragraphs, the second superconducting sub-circuit comprises a first feeding Josephson transmission line coupled to a first terminal of the quantizing inductor, and a second feeding Josephson transmission line coupled to a second terminal of the quantizing inductor. The first feeding Josephson transmission line is configured to source the first circulating current and sink the second circulating current. The second feeding Josephson transmission line is configured to source the second circulating current and sink the first circulating current.

In another exemplary embodiment, which may be combined with one or more of the embodiments of the preceding paragraphs, the second superconducting sub-circuit comprises a first SFQ pulse multiplier and a second SFQ pulse multiplier. The first SFQ pulse multiplier is configured to generate a first set of SFQ pulses in response to the first SFQ pulse injected into the second superconducting sub-circuit, and apply the first set of SFQ pulses to the first feeding Josephson transmission line to generate the first circulating current. The second SFQ pulse multiplier is configured to generate a second set of SFQ pulses in response to the second SFQ pulse injected into the second superconducting sub-circuit, and apply the second set of SFQ pulses to the second feeding Josephson transmission line to generate the second circulating current.

In another exemplary embodiment, which may be combined with one or more of the embodiments of the preceding paragraphs, the square current pulses have a pulse magnitude which corresponds to

$$m * \frac{{Φ}_{0}}{{L}_{Q}} ,$$

where m denotes a number of SFQ pulses in the first set of SFQ pulses, do is the superconducting magnetic flux quantum, and where L_{Q} is an inductance value of the quantizing inductor.

In another exemplary embodiment, which may be combined with one or more of the embodiments of the preceding paragraphs, the quantizing inductor is mutually coupled to a superconducting device and generates a magnetic flux bias in response to the square current pulses, which is applied to the superconducting device, where the superconducting device is one of a superconducting inductor and a superconducting loop comprising Josephson junctions.

Another exemplary embodiment includes a device which comprises a superconducting square pulse waveform generator which comprises a first superconducting sub-circuit and a second superconducting sub-circuit which comprises a quantizing inductor. The first superconducting sub-circuit is configured to receive an SFQ pulse applied to an input port of the superconducting square pulse waveform generator, and propagate the SFQ pulse around the first superconducting sub-circuit to periodically inject (i) a first SFQ pulse into the second superconducting sub-circuit to cause a first circulating current to flow in a first direction through the quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

In another exemplary embodiment, which may be combined with one or more of the embodiments of the preceding paragraphs, the first superconducting sub-circuit comprises a first Josephson transmission line having a fixed propagation delay which sets a pulse period of a continuous sequence of square current pulses, and the second superconducting sub-circuit comprises a second Josephson transmission line having fixed propagation delay which sets a pulse width of the square current pulses.

In another exemplary embodiment, which may be combined with one or more of the embodiments of the preceding paragraphs, the square current pulses have a pulse magnitude which is proportional to

$$\frac{{Φ}_{0}}{{L}_{Q}} ,$$

where Φ₀ is the superconducting magnetic flux quantum, and where L_{Q} is an inductance value of the quantizing inductor.

In another exemplary embodiment, which may be combined with one or more of the embodiments of the preceding paragraphs, the first superconducting sub-circuit comprises a first SFQ pulse splitter, and a second SFQ splitter. The first SFQ pulse splitter is configured to inject the first SFQ pulse into the second superconducting sub-circuit to cause the first circulating current to flow in the first direction through the quantizing inductor. The second SFQ pulse splitter is configured to inject the second SFQ pulse into the second superconducting sub-circuit to cause the second circulating current to flow through the quantizing inductor in a second direction.

In another exemplary embodiment, which may be combined with one or more of the embodiments of the preceding paragraphs, the second superconducting sub-circuit comprises a first feeding Josephson transmission line coupled to a first terminal of the quantizing inductor, and a second feeding Josephson transmission line coupled to a second terminal of the quantizing inductor. The first feeding Josephson transmission line is configured to source the first circulating current and sink the second circulating current. The second feeding Josephson transmission line is configured to source the second circulating current and sink the first circulating current.

In another exemplary embodiment, which may be combined with one or more of the embodiments of the preceding paragraphs, the second superconducting sub-circuit comprises a first SFQ pulse multiplier and a second SFQ pulse multiplier. The first SFQ pulse multiplier is configured to generate a first set of SFQ pulses in response to the first SFQ pulse injected into the second superconducting sub-circuit, and apply the first set of SFQ pulses to the first feeding Josephson transmission line to generate the first circulating current. The second SFQ pulse multiplier is configured to generate a second set of SFQ pulses in response to the second SFQ pulse injected into the second superconducting sub-circuit, and apply the second set of SFQ pulses to the second feeding Josephson transmission line to generate the second circulating current.

In another exemplary embodiment, which may be combined with one or more of the embodiments of the preceding paragraphs, the square current pulses have a pulse magnitude which corresponds to

$$m * \frac{{Φ}_{0}}{{L}_{Q}} ,$$

where m denotes a number of SFQ pulses in the first set of SFQ pulses, Φ₀ is the superconducting magnetic flux quantum, and where L_{Q} is an inductance value of the quantizing inductor.

In another exemplary embodiment, which may be combined with one or more of the embodiments of the preceding paragraphs, the quantizing inductor is mutually coupled to a superconducting device and generates a magnetic flux bias in response to the square current pulses, which is applied to the superconducting device. The superconducting device is a superconducting inductor or a superconducting loop comprising Josephson junctions.

Another exemplary embodiment includes a method which comprises receiving, by a superconducting square pulse waveform generator, a single flux quantum (SFQ) pulse, and generating, by the superconducting square pulse waveform generator, a continuous sequence of square current pulses in response to the SFQ pulse, where generating the continuous sequence of square current pulses comprises propagating the received SFQ pulse around a first superconducting sub-circuit of the superconducting square pulse waveform generator to periodically inject (i) a first SFQ pulse into a second superconducting sub-circuit of the superconducting square pulse waveform generator to cause a first circulating current to flow in a first direction through a quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

In another exemplary embodiment, which may be combined with one or more of the embodiments of the preceding paragraphs, the method includes tuning a propagation delay of a first Josephson transmission line of the first superconducting sub-circuit to tune a pulse period of the continuous sequence of square current pulses, and tuning a propagation delay of a second Josephson transmission line of the second superconducting sub-circuit to tune a pulse width of the square current pulses.

In another exemplary embodiment, which may be combined with one or more of the embodiments of the preceding paragraphs, the square current pulses have a pulse magnitude which is proportional to

$$\frac{{Φ}_{0}}{{L}_{Q}} ,$$

where Φ₀ is the superconducting magnetic flux quantum, and where L_{Q} is an inductance value of the quantizing inductor.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise superconducting quantum devices (e.g., quantum processors, quantum bits, Josephson junctions, Josephson ring modulators, quantum-limited amplifiers (QLAs), qubit couplers, microwave switches, isolator circuits, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

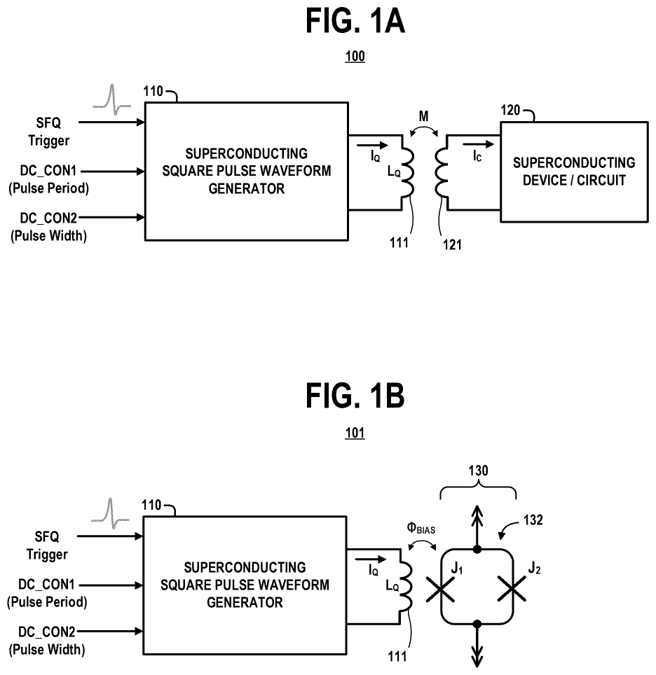

FIG. 1A schematically illustrates a device which comprises a superconducting square pulse waveform generator, according to an exemplary embodiment of the disclosure. In particular, FIG. 1A schematically illustrates a device 100 which comprises a superconducting square pulse waveform generator 110, a primary inductor 111, a superconducting device/circuit 120, and a secondary inductor 121. The superconducting square pulse waveform generator 110 comprises a self-oscillating square pulse generator circuit which is configured to generate a square pulse waveform in response to a single SFQ trigger pulse applied thereto. In some embodiments, the superconducting square pulse waveform generator 110 generates a square pulse waveform as a quantized current I_{Q} which flows through the primary inductor 111. The primary inductor 111 comprises a superconducting inductor having a quantizing inductance L_{Q} to which one or more SFQ pulses are applied to generate the quantized current I_{Q} which flows through the primary inductor 111 to thereby generate a magnetic flux. The secondary inductor 121 comprises a superconducting inductor which is disposed adjacent to the primary inductor 111. The primary inductor 111 and the secondary inductor 121 are magnetically coupled with a mutual inductance M such that the magnetic flux generated by the primary inductor 111 induces an electromotive force (EMF) in the secondary inductor 121 which, in turn, produces a corresponding current I_{C} that comprises a square wave control signal that is applied to the superconducting device/circuit 120.

In some embodiments, the superconducting square pulse waveform generator 110 comprises a tunable architecture which enables in-situ tuning of a pulse period (or frequency) and/or a pulse width (or duty cycle) of a square pulse waveform using one or more DC control signals. For example, as schematically shown in FIG. 1A, the superconducting square pulse waveform generator 110 is responsive to a first DC control signal DC_CON1 to tune the pulse period (or pulse-to-pulse spacing) of a square pulse waveform that is generated by the superconducting square pulse waveform generator 110. In addition, the superconducting square pulse waveform generator 110 is responsive to a second DC control signal DC_CON2 to tune the pulse width (or duty cycle) of square wave pulses that are generated by the superconducting square pulse waveform generator 110. In other embodiments, the superconducting square pulse waveform generator 110 comprises a non-tunable architecture in which the superconducting square pulse waveform generator 110 is designed to generate a square pulse waveform having a fixed period and fixed pulse width, for controlling a specific quantum device or quantum circuit.

In some embodiments, the superconducting device/circuit 120 may be any type of superconducting quantum device or quantum circuitry, such as a high-speed microwave switch or signal routing circuitry, which is controlled using high-speed clock signals (e.g., square wave clock signals). In other embodiments, the superconducting device/circuit 120 may be any type of superconducting quantum device or quantum circuitry, such as quantum bits, quantum bit couplers, etc., which is controlled by flux-bias tuning using square wave pulses, etc. In some embodiments, the secondary inductor 121 is a component of a given superconducting quantum device that is controlled using square wave pulses that are generated by the superconducting square pulse waveform generator 110. In other embodiments, a magnetic flux bias ØBIAS that is generated by the quantized current I_{Q} flowing through the superconducting primary inductor 111 is magnetically threaded through a superconducting loop of a quantum circuit or device to change operating characteristics of the quantum circuit or device.

For example, FIG. 1B schematically illustrates a device which comprises a superconducting square pulse waveform generator, according to an exemplary embodiment of the disclosure. In particular, FIG. 1B schematically illustrates a device 101 which is similar to the device 100 of FIG. 1A, except that the device 101 comprises a quantum device/circuit 130 which comprises a DC-SQUID 132 that is tuned by a magnetic flux bias @BIAS that is generated by the quantized current I_{Q} flowing through the superconducting inductor 111. The DC-SQUID 132 comprises a first Josephson junction J1 and a second Josephson junction J2, which have non-linear inductances, and which are connected in parallel to form a superconducting loop (referred to as a SQUID loop) through which the magnetic flux bias Φ_{BIAS} is threaded to tune the operating characteristics of the superconducting quantum circuit/device 130 which implements the DC-SQUID 132, as is known in the art. The DC-SQUID 132 has a flux-tunable inductance that is controlled by an amount of magnetic flux bias @BIAS that is threaded through the SQUID loop to modulate an effective inductance of the DC-SQUID 132 to different impedance states, e.g., a low inductance state (low impedance state), or a high inductance state, as desired for a given application.

In some embodiments, the DC-SQUID 132 can be implemented as a component of a flux-tunable quantum bit. In other embodiments, the DC-SQUID 132 can be implemented as an RF switch device (e.g., ground-shunted microwave switch device, or series-connected switch device) or a component of a switch circuit. For example, the DC-SQUID 132 can be a superconducting switch node that is disposed in series between a first port and a second port, wherein the superconducting switch node can be placed in either (i) a low inductance state to allow the transmission of RF energy between the first and second ports, (ii) a high inductance state to block or suppress the transmission of RF energy between the first and second ports.

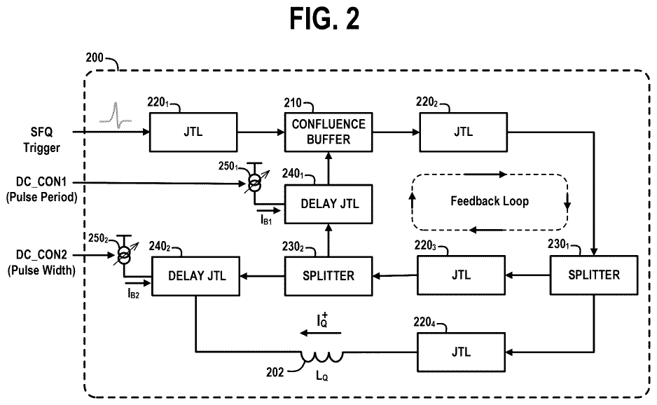

FIG. 2 schematically illustrates a superconducting square pulse waveform generator, according to an exemplary embodiment of the disclosure. In particular, FIG. 2 schematically illustrates a superconducting square pulse waveform generator 200 which comprises a superconducting inductor 202, a confluence buffer 210, a plurality of Josephson transmission lines (JTLs) including a first JTL 220₁, a second JTL 220₂, a third JTL 220₃, and a fourth JTL 220₄, a first SFQ pulse splitter 230₁ (or first splitter 230₁), a second SFQ pulse splitter 230₂ (or second splitter 230₂), a first delay JTL 240₁, a second delay JTL 240₂, a first DC bias current generator 250₁, and a second DC bias current generator 250₂. The superconducting square pulse waveform generator 200 comprises an SFQ-based circuit with a self-oscillating circuit architecture which is configured to generate a continuous square pulse waveform in response to a single SFQ trigger pulse that is applied to an input port of the superconducting square pulse waveform generator 200.

As schematically illustrated in FIG. 2, the first JTL 220₁ comprises an input port that is coupled to the input port of the superconducting square pulse waveform generator 200. The confluence buffer 210 comprises (i) a first input port that is coupled to an output port of the first JTL 220₁, (ii) a second input port that is coupled to an output port of the first delay JTL 240₁, and (iii) an output port that is coupled to an input port of the second JTL 220₂. An output port of the second JTL 220₂ is coupled to an input port of the first splitter 230₁. The first splitter 230₁ comprises a first output port that is coupled to an input port of the third JTL 220₃, and a second output port that is coupled to an input port of the fourth JTL 220₄. The third JTL 220₃ comprises an output port that is coupled to an input port of the second splitter 230₂. The fourth JTL 220₄ comprises an output port that is coupled to a first terminal of the superconducting inductor 202. The second splitter 230₂ comprises a first output port that is coupled to an input port of the first delay JTL 240₁, and a second output port that is coupled to an input port of the second delay JTL 240₂. The second delay JTL 240₂ comprises an input/output port that is coupled to a second terminal of the superconducting inductor 202.

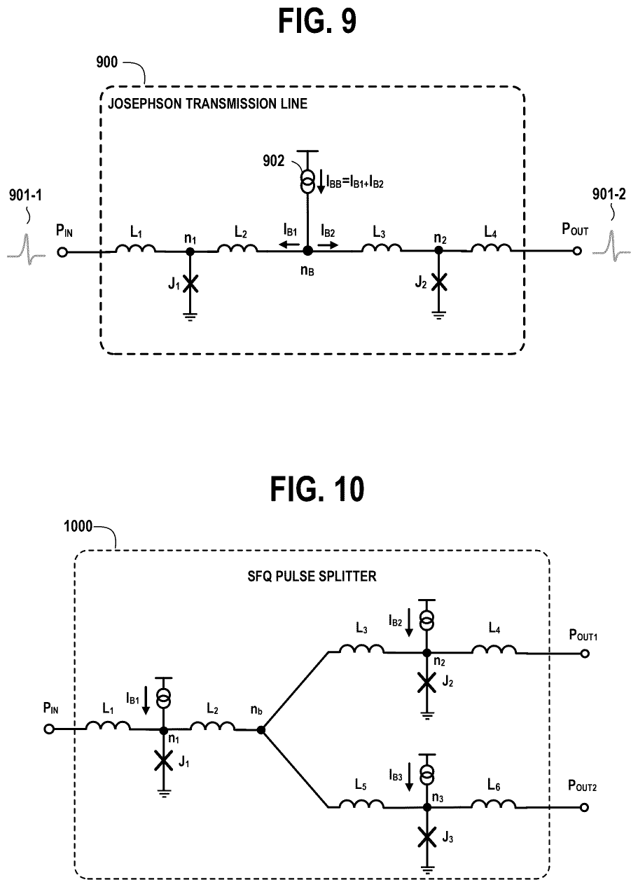

In an exemplary embodiment, the confluence buffer 210, the first, second, third, and fourth JTLs 220₁, 220₂, 220₃, and 220₄, the first and second splitters 230₁ and 230₂, and the first and second delay JTLs 240₁ and 240₂ are implemented using RSFQ circuits. The JTLs 220₁, 220₂, 220₃, and 220₄, serve as buffers and SFQ pulse repeaters with fixed propagation delays. In some embodiments, each JTL 220₁, 220₂, 220₃, and 220₄ is implemented using a two-stage, non-amplifying JTL architecture, an exemplary embodiment of which will be discussed in further detail below in conjunction with FIG. 9. The first and second splitters 230₁ and 230₂ are SFQ pulse splitter circuits that are configured to receive an SFQ pulse and output two independent SFQ pulses. An exemplary embodiment of a circuit architecture for implementing an SFQ pulse splitter will be discussed in further detail below in conjunction with FIG. 10.

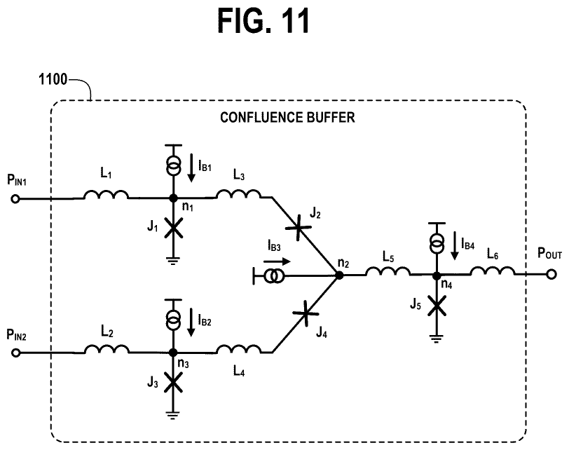

The confluence buffer 210 is essentially equivalent to a logical OR gate. The confluence buffer 210 is configured to output an SFQ pulse from the output port thereof when an input SFQ pulse arrives at either the first input port or the second input port of the confluence buffer 210. The confluence buffer 210 is configured to prevent an SFQ pulse from being output from the second input port when an input SFQ pulse is applied to the first input port, and vice versa. An exemplary embodiment of a circuit architecture for implementing the confluence buffer 210 will be discussed in further detail below in conjunction with FIG. 11.

The first and second delay JTLs 240₁ and 240₂ comprise JTL circuits which serve as buffers and SFQ pulse repeaters, but are configured to have adjustable propagation delays (or controllable delays) that are set by adjusting DC bias currents that are applied to the first and second delay JTLs 240₁ and 240₂. For example, as schematically shown in FIG. 2, the first DC bias current generator 250₁ generates a first DC bias current I_{B1} that is applied to the first delay JTL 240₁, wherein the first DC bias current generator 250₁ is responsive to a first control signal DC_CON1 to set a magnitude of the first DC bias current I_{B1}. Similarly, the second DC bias current generator 250₂ generates a second DC bias current I_{B2} that is applied to the second delay JTL 240₂, wherein the second DC bias current generator 250₂ is responsive to a second control signal DC_CON2 to set a magnitude of the second DC bias current I_{B1}. The propagation delays of the first delay JTL 240₁ and the second delay JTL 240₂ can be increased by decreasing the magnitude of the first DC bias current I_{B1} and the second DC bias current I_{B2}, respectively. Conversely, the propagation delays of the first delay JTL 240₁ and the second delay JTL 240₂ can be decreased by increasing the magnitude of the first DC bias current I_{B1} and the second DC bias current I_{B2}, respectively.

As schematically illustrated in FIG. 2, the confluence buffer 210, the second JTL 220₂, the first splitter 230₁, the third JTL 220₃, the second splitter 230₂, and the first delay JTL 240₁ collectively form a first superconducting sub-circuit which comprises a feedback loop, wherein the first superconducting sub-circuit is configured to generate a series of SFQ pulses (or SFQ pulse train) with a pulse-to-pulse spacing (or pulse period) that is controllably set based on the magnitude of the first DC bias current I_{B1} which is generated by the first DC bias current generator 250₁ in response to the first control signal DC_CON1, and applied to the first delay JTL 240₁. In this regard, the first delay JTL 240₁ provides a controllable propagation delay in the feedback loop to set the pulse-to-pulse spacing (period) of a continuous square pulse waveform that is generated by the superconducting square pulse waveform generator 200. While the confluence buffer 210, the second JTL 220₂, the first splitter 230₁, the third JTL 220₃, and the second splitter 230₂ in the feedback loop collectively provide a fixed delay component (on the order of picoseconds) of the pulse-to-pulse spacing (period) of the continuous square pulse waveform, such fixed delay is relatively small as compared to the tunable amount of delay that is provided by the first delay JTL 240₁ in the feedback loop, based on the magnitude of the DC bias current I_{B1} which is adjusted to set the pulse-to-pulse spacing (period) of the continuous square pulse waveform that is generated by the superconducting square pulse waveform generator 200.

Furthermore, in the exemplary embodiment of FIG. 2, the fourth JTL 220₄, the superconducting inductor 202, and the second delay JTL 240₂ collectively form a second superconducting sub-circuit which comprises a superconducting loop that allows a circulating current I_{Q} to flow when an SFQ pulse is injected into the second superconducting sub-circuit from the first superconducting sub-circuit (e.g., when an SFQ pulse is output from the first splitter 230₁ and applied to the fourth JTL 220₄). After a single SFQ pulse (single fluxon) is applied to the input of the fourth JTL 220₄, a positive circulating current

$${I}_{Q}^{+}$$

is generated with a magnitude of

$${I}_{Q}^{+} = \frac{{Φ}_{0}}{{L}_{Q}} ,$$

where L_{Q} denotes the quantizing inductance of the superconducting inductor 202, and where Φ₀ denotes the superconducting magnetic flux quantum. For purposes of discussion, an arrow shown in FIG. 2 represents a direction of positive circulating current

$${I}_{Q}^{+}$$

flow through the superconducting inductor 202.

The second splitter 230₂ (of the first superconducting sub-circuit) is configured to inject an SFQ pulse into the second superconducting sub-circuit from the first superconducting sub-circuit (e.g., an SFQ pulse is output from the second splitter 230₂ and applied to the second delay JTL 240₂). After some time delay, the second delay JTL 240₂ outputs an SFQ pulse into the superconducting loop, which generates a circulating current (or negative current) in the superconducting loop with a magnitude of

$${I}_{Q}^{-} = \frac{{Φ}_{0}}{{L}_{Q}} ,$$

but which flows in a direction (negative current flow) that is opposite to the direction of positive current flow represented by the arrow. As such, the second delay JTL 240₂ injecting the SFQ pulse into the superconducting loop causes a negative current to flow in the superconducting loop with a magnitude of

$${I}_{Q}^{-} = - \frac{{Φ}_{0}}{{L}_{Q}}$$

which essentially cancels/annihilates the positive flowing current

$${I}_{Q}^{+} = \frac{{Φ}_{0}}{{L}_{Q}} ,$$

whereby the oppositely flowing currents cancel each other, resulting in I_{Q}=0. The amount of time that the circulating current I_{Q} flows corresponds to a pulse width of the square wave current pulses that are generated by the superconducting square pulse waveform generator 200.

More specifically, the pulse width is controllably set based on the magnitude of the second DC bias current I_{B2} which is generated by the second DC bias current generator 250₂ in response to the second control signal DC_CON2, and applied to the second delay JTL 240₂. In this regard, the second delay JTL 240₂ provides a controllable propagation delay to inject an SFQ pulse into the superconducting loop to generate a negative current

$${I}_{Q}^{-}$$

which cancels the positive current

$${I}_{Q}^{+} ,$$

thereby resulting in a net current of

$${I}_{Q}^{+} + {I}_{Q}^{-} = 0 .$$

While the second splitter 230₂ provides a fixed delay component (on the order of picoseconds) which partially defines the pulse width of the square wave pulses that are generated by the superconducting square pulse waveform generator 200, such fixed delay component is relatively small as compared to the controllable amount of delay that is provided by the second delay JTL 240₂, which primarily defines the pulse width.

In this regard, FIG. 2 schematically illustrates an exemplary embodiment of a superconducting square pulse waveform generator which comprises a self-oscillating circuit that is configured to generate a continuous sequence of square current pulses, in response to a single SFQ trigger pulse that is applied to an input port of the superconducting square pulse waveform generator. The self-oscillating circuit comprises a first superconducting sub-circuit (e.g., the confluence buffer 210, the second JTL 220₂, the first splitter 230₁, the third JTL 220₃, the second splitter 230₂, and the first delay JTL 240₁, which form a feedback loop) and a second superconducting sub-circuit which comprises the quantizing superconducting inductor 202. The first superconducting sub-circuit is configured to receive the SFQ pulse applied to the input port of the superconducting square pulse waveform generator, and propagate the SFQ pulse around the first superconducting sub-circuit to periodically inject (i) a first SFQ pulse into the second superconducting sub-circuit to cause a first circulating current

$$( e . g . , positive current {I}_{Q}^{+} )$$

to flow in a first direction through the quantizing superconducting inductor 202, and (ii) a second SFQ pulse into the second superconducting sub-circuit to cause a second circulating current

$$( e . g . , negative current {I}_{Q}^{-} )$$

to flow through the quantizing inductor in a second direction, opposite the first direction, to cancel the first current and thereby generate a square current pulse.

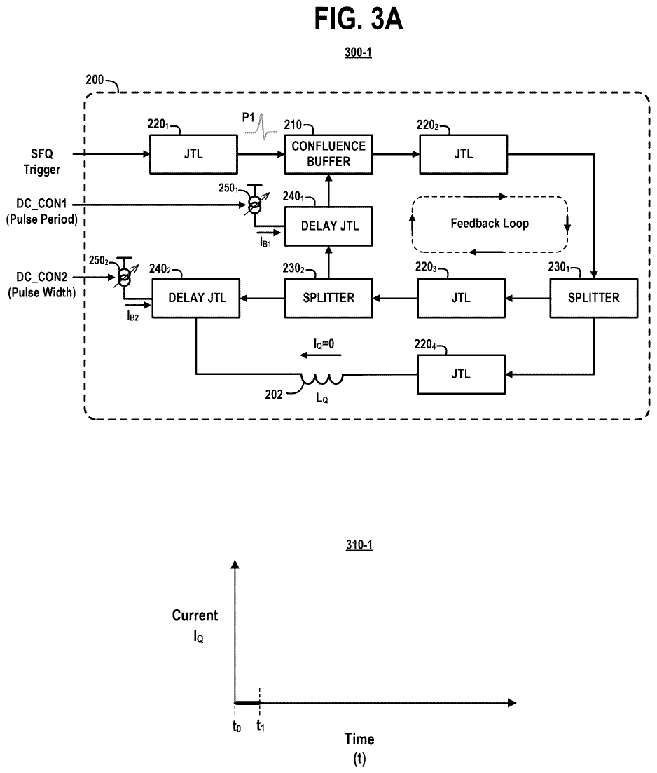

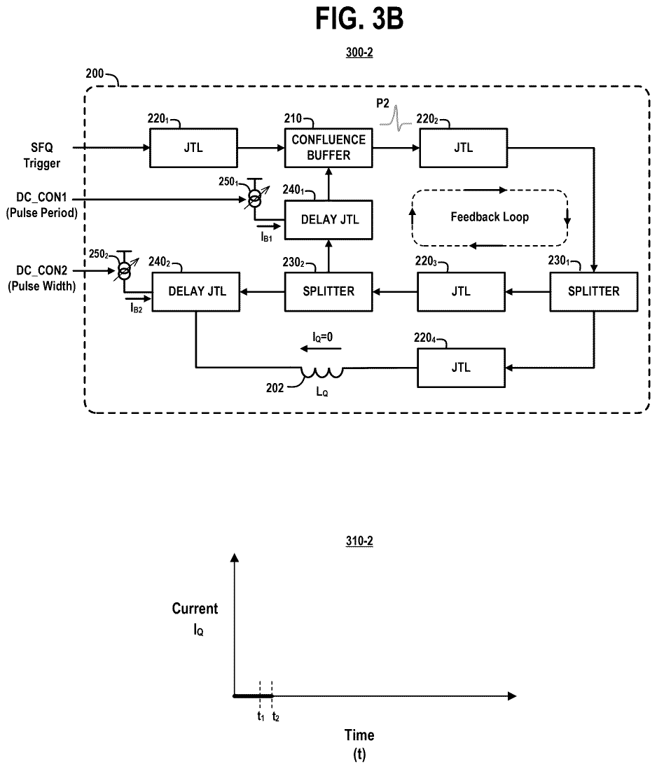

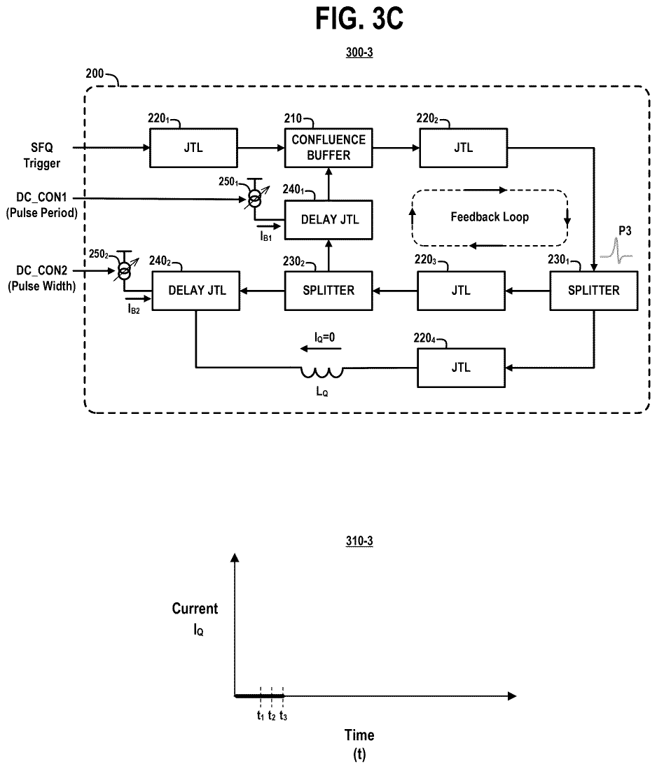

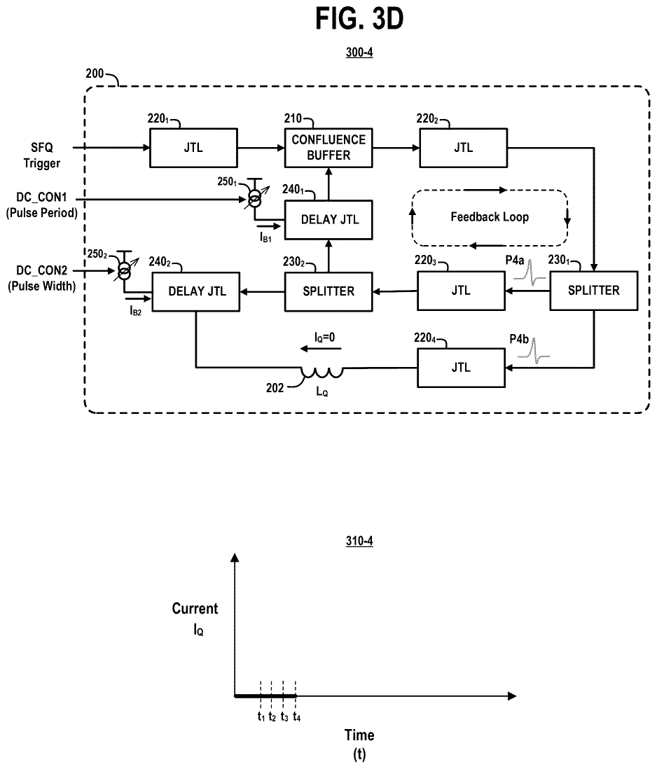

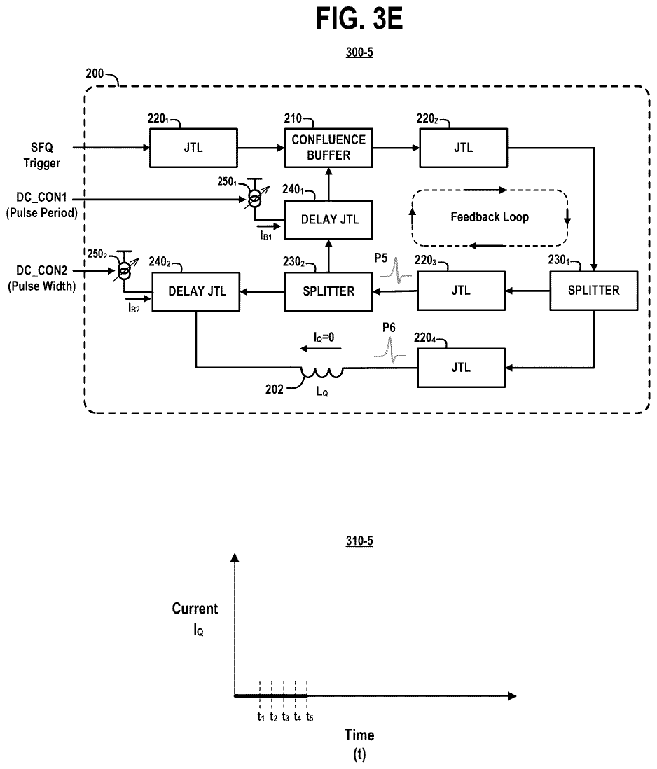

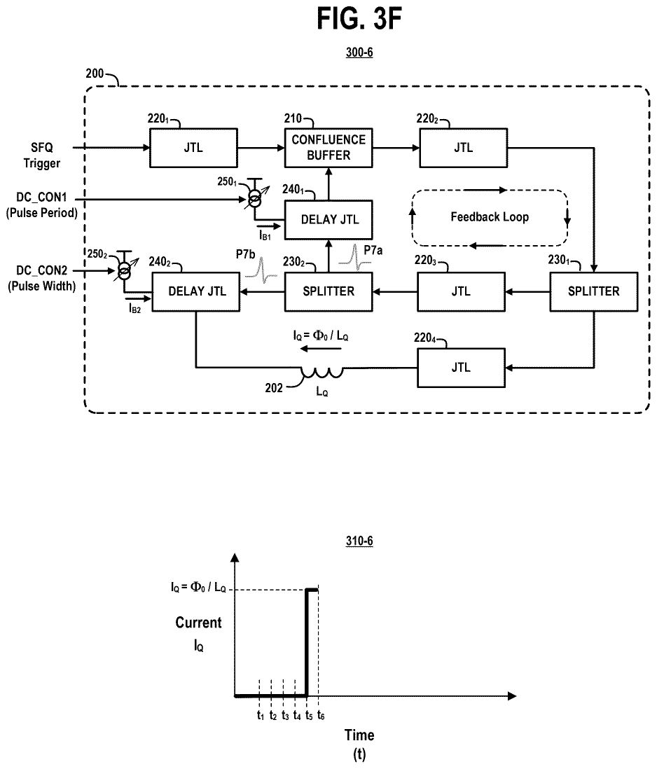

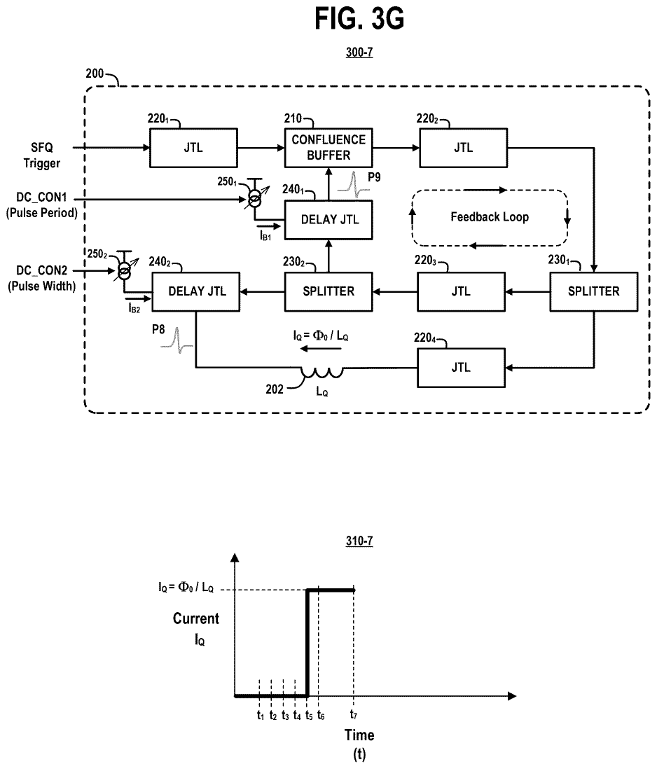

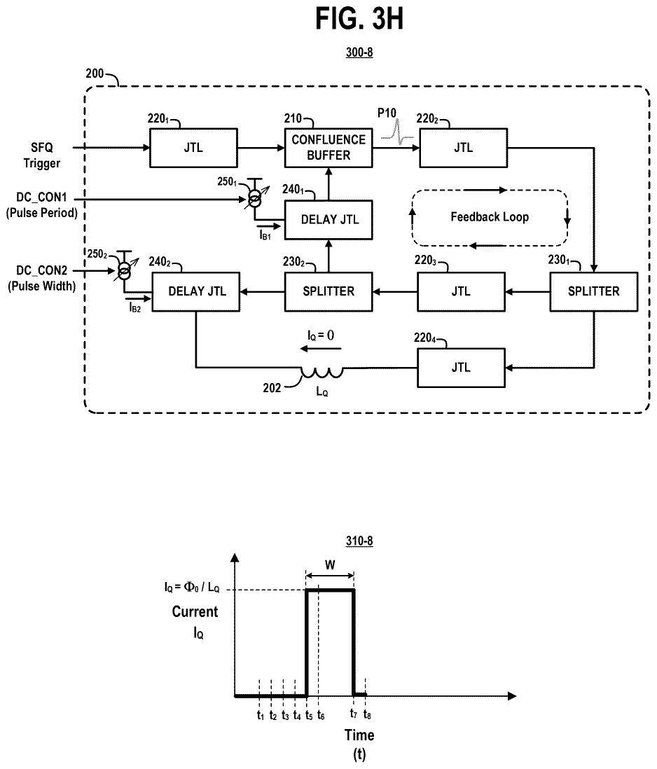

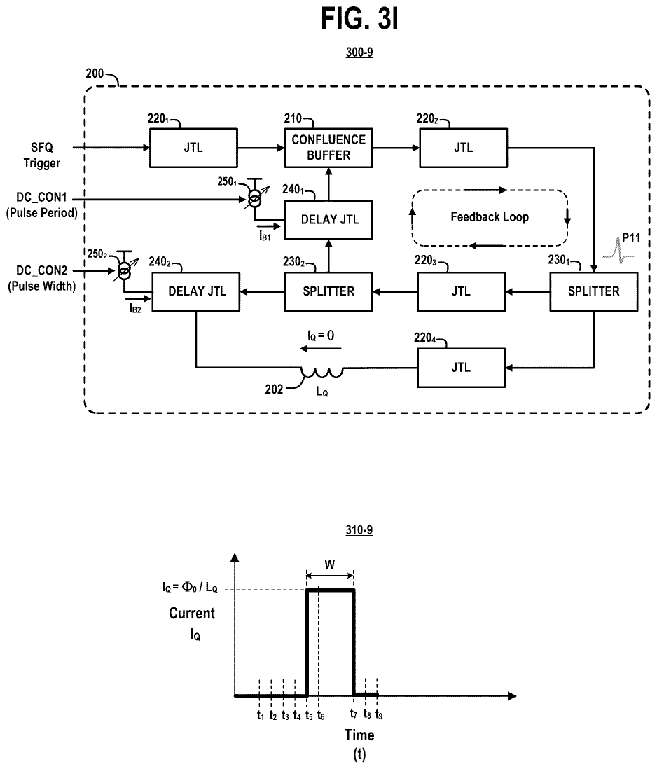

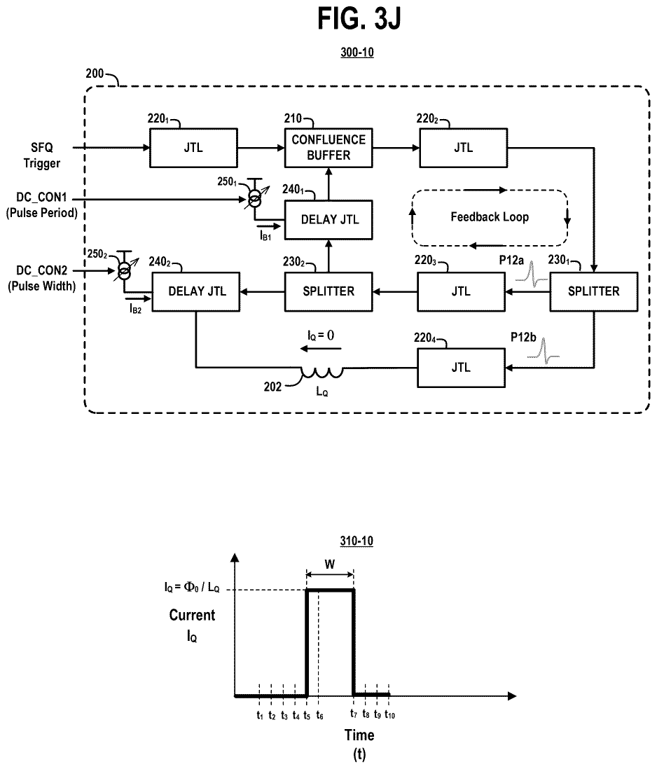

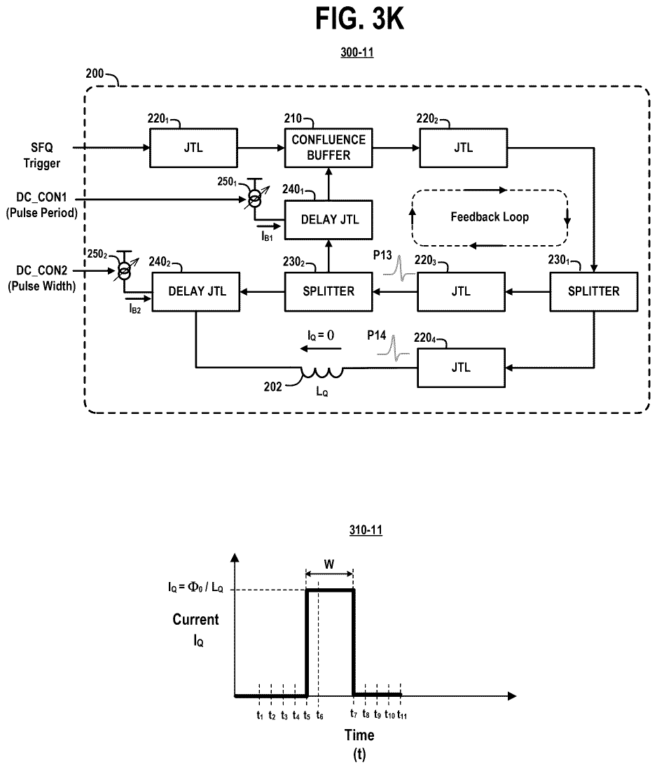

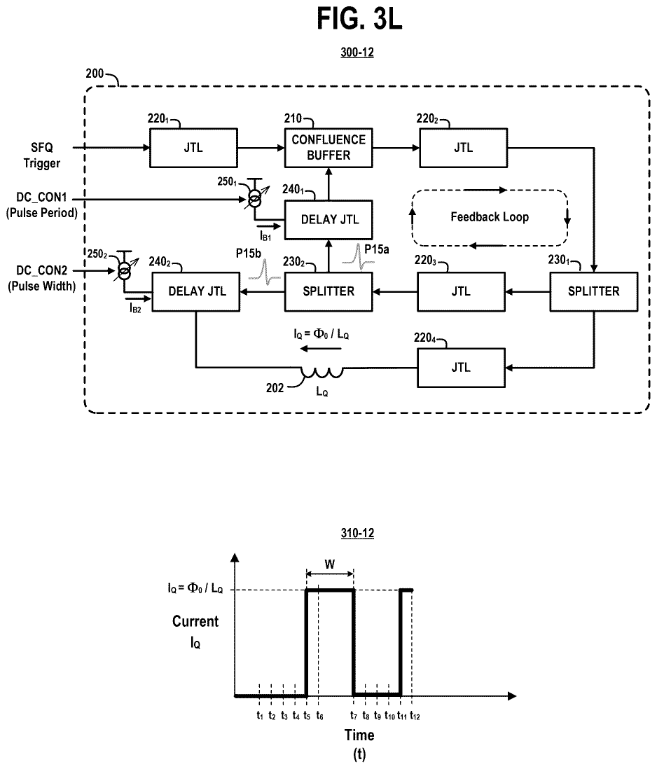

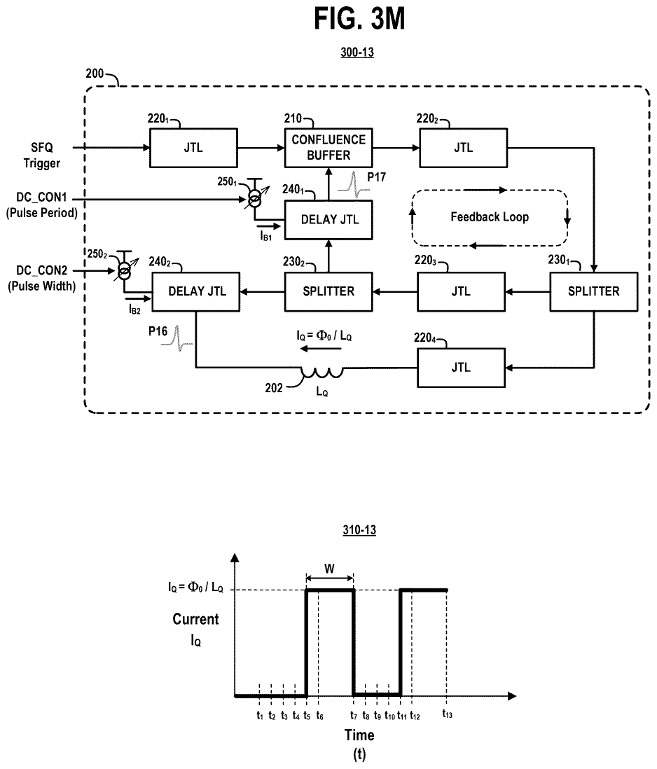

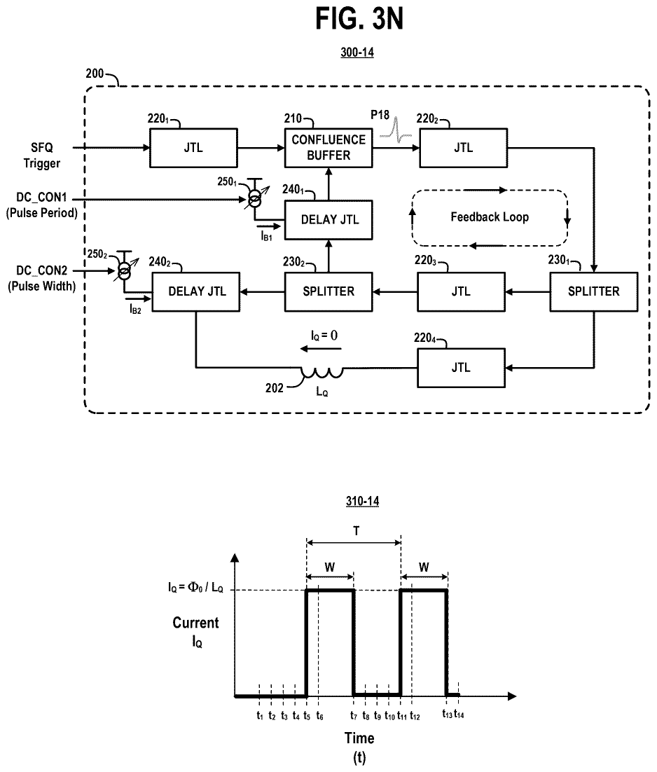

FIGS. 3A, 3B, 3C, 3D, 3E, 3F, 3G, 3H, 3I, 3J, 3K, 3L, 3M, and 3N schematically illustrate an exemplary mode of operation of a superconducting square pulse waveform generator, according to an exemplary embodiment of the disclosure. In particular, for purposes of discussion, FIGS. 3A-3N will be discussed in the context of the superconducting square pulse waveform generator 200 of FIG. 2, where it is assumed that the confluence buffer 210, the first, second, third, and fourth JTLs 220₁, 220₂, 220₃, and 220₄, and the first and second splitters 230₁ and 230₂, each have a fixed (non-tunable) propagation delay which is nominally the same, and that the first and second delay JTLs 240₁ and 240₂ have tunable propagation delays that are set to generate a continuous square pulse waveform having a duty cycle of about 50%.

Moreover, for purposes of illustration, FIGS. 3A-3N depict timing diagrams which progressively show a square pulse waveform that is generated over time by operation of the superconducting square pulse waveform generator 200. At time to, it is assumed that the operation of the superconducting square pulse waveform generator 200 is triggered/initiated in response to an SFQ trigger pulse applied to the input port of the superconducting square pulse waveform generator 200, which, in turn, is applied to the input port of the first JTL 220₁. The SFQ trigger pulse is generated by an SFQ pulse source, which can be any auxiliary control circuit running SFQ logic in a cryogenic environment.

FIG. 3A illustrates an operating state 300-1 of the superconducting square pulse waveform generator 200 at time t₁, where the first JTL 220₁ outputs an SFQ pulse P1 in response to the SFQ trigger pulse applied to the input port thereof, after a fixed propagation delay time. The SFQ pulse P1 is applied to the first input port of the confluence buffer 210. In addition, FIG. 3A illustrates a timing diagram 310-1 which shows an output current waveform I_{Q} for the period t₀ to t₁, where the output current I_{Q} remains at I_{Q}=0.

Next, FIG. 3B illustrates an operating state 300-2 of the superconducting square pulse waveform generator 200 at time t₂, where the confluence buffer 210 outputs an SFQ pulse P2 in response to the SFQ pulse P1 applied to the input port thereof, after a fixed propagation delay time. The SFQ pulse P2 is applied to the input port of the second JTL 220₂. In addition, FIG. 3B illustrates a timing diagram 310-2 which further shows the output current waveform I_{Q} for the period t₁ to t₂, where the output current I_{Q} remains at I_{Q}=0.

Next, FIG. 3C illustrates an operating state 300-3 of the superconducting square pulse waveform generator 200 at time t₃, where the second JTL 220₂ outputs an SFQ pulse P3 in response to the SFQ pulse P2 applied to the input port thereof, after a fixed propagation delay time. The SFQ pulse P3 is applied to the input port of the first splitter 230₁. In addition, FIG. 3C illustrates a timing diagram 310-3 which further shows the output current waveform I_{Q} for the period t₂ to t₃, where the output current I_{Q} remains at I_{Q}=0.

Next, FIG. 3D illustrates an operating state 300-4 of the superconducting square pulse waveform generator 200 at time t₄, where the first splitter 230₁ outputs a first SFQ pulse P4a and a second SFQ pulse P4b, in response to the SFQ pulse P3 applied to the input port thereof, after a fixed propagation delay time. The first SFQ pulse P4a is applied to the input port of the third JTL 220₃, and the second SFQ pulse P4b is applied to the input port of the fourth JTL 220₄. In addition, FIG. 3D illustrates a timing diagram 310-4 which further shows the output current waveform I_{Q} for the period t₃ to t₄, where the output current I_{Q} remains at I_{Q}=0.

Next, FIG. 3E illustrates an operating state 300-5 of the superconducting square pulse waveform generator 200 at time t₅, where (i) the third JTL 220₃ outputs an SFQ pulse P5, in response to the SFQ pulse P4a applied to the input port thereof, after a fixed propagation delay time, and (ii) the fourth JTL 220₄ outputs an SFQ pulse P6, in response to the SFQ pulse P4b applied to the input port thereof, after a fixed propagation delay time. The SFQ pulse P5 is applied to the input port of the second splitter 230₂. The SFQ pulse P6 is applied to the superconducting inductor 202. In addition, FIG. 3E illustrates a timing diagram 310-5 which further shows the output current waveform I_{Q} for the period t₄ to t₅, where the output current I_{Q} remains at I_{Q}=0.

Next, FIG. 3F illustrates an operating state 300-6 of the superconducting square pulse waveform generator 200 at time t₆, where the second splitter 230₂ outputs a first SFQ pulse P7a and a second SFQ pulse P7b, in response to the SFQ pulse P5 applied to the input port thereof, after a fixed propagation delay time. The first SFQ pulse P7a is applied to the input port of the first delay JTL 240₁, and the second SFQ pulse P7b is applied to the input port of the second delay JTL 240₂. In addition, FIG. 3F illustrates a timing diagram 310-6 which further shows the output current waveform I_{Q} for the period t₅ to t₆, where the output current I_{Q} abruptly increases (just after t₅) to

$${I}_{Q} = \frac{{Φ}_{0}}{{L}_{Q}} .$$

The output current I_{Q} is generated as a result of applying the SFQ pulse P6 (FIG. 3E), which is output from the fourth JTL 220₄, to the superconducting inductor 202 with the quantizing inductance L_{Q}. As noted above, the fourth JTL 220₄, the superconducting inductor 202, and the second delay JTL 240₂ collectively provide a superconducting loop that allows the output current I_{Q} to circulate, wherein the second delay JTL 240₂ sinks the circulating current to ground, and the fourth JTL 220₄ provides a return path from ground to circulate the current through the inductor 202. The injected circulating current does not induce any further switching in the circuit.

Next, FIG. 3G illustrates an operating state 300-7 of the superconducting square pulse waveform generator 200 at time t₇, where (i) the second delay JTL 240₂ outputs an SFQ pulse P8, in response to the SFQ pulse P7b applied to the input port thereof, after a selectively tuned propagation delay time of the second delay JTL 240₂, and (ii) the first delay JTL 240₁ outputs an SFQ pulse P9, in response to the SFQ pulse P7a applied to the input port thereof, after a selectively tuned propagation delay time of the first delay JTL 240₁. The SFQ pulse P8 is applied to the superconducting inductor 202, and the SFQ pulse P9 is applied to the second input port of the confluence buffer 210. In addition, FIG. 3G illustrates a timing diagram 310-7 which further shows the output current waveform I_{Q} for the period t₆ to t₇, where the output current I_{Q} remains at

$${I}_{Q} = \frac{{Φ}_{0}}{{L}_{Q}}$$

up to time t₇.

Next, FIG. 3H illustrates an operating state 300-8 of the superconducting square pulse waveform generator 200 at time t₈, where (i) the confluence buffer 210 outputs an SFQ pulse P10 in response to the SFQ pulse P9 applied to the input port thereof, after a fixed propagation delay time, and where (ii) the SFQ pulse P8 (antifluxon), which is output from the second delay JTL 240₂ and injected into the superconducting current loop, causes a negative current

$${I}_{Q}^{-} = - \frac{{Φ}_{0}}{{L}_{Q}}$$

to be generated and flow through the superconducting inductor 202. The negative current

$${I}_{Q}^{-} = - \frac{{Φ}_{0}}{{L}_{Q}}$$

essentially cancels the positive current

$${I}_{Q}^{+} = \frac{{Φ}_{0}}{{L}_{Q}}$$

through the superconducting inductor 202, resulting in a net current of

$${I}_{Q}^{+} + {I}_{Q}^{-} = 0.$$

In addition, FIG. 3H illustrates a timing diagram 310-8 which further shows the output current waveform I_{Q} for the period t₇ to t₈, where the output current I_{Q} abruptly decreases (just after t₇) to I_{Q}=0, as a result of the SFQ pulse P8 that is output from the second delay JTL 240₂ and injected into the superconducting current loop. The timing diagram 310-8 illustrates a resulting square-shaped current pulse having a given pulse width (denoted W). The pulse width W is defined by (i) a fixed delay time (t₆-t₅) due to the fixed propagation delay of the second splitter 230₂, and (ii) a tunable delay time (t₇-t₆) due to the selectively tuned propagation delay of the second delay JTL 240₂.

Following the operating state 300-8 of the superconducting square pulse waveform generator 200 as shown in FIG. 3H, the sequence of pulse propagation and current pulse generation as discussed above in conjunction with FIGS. 3C-3H is repeated to generate additional current pulses and thereby generate a continuous square pulse waveform. For example, FIG. 3I illustrates an operating state 300-9 of the superconducting square pulse waveform generator 200 at time to, where the second JTL 220₂ outputs an SFQ pulse P11 in response to the SFQ pulse P10 applied to the input port thereof, after a fixed propagation delay time. The SFQ pulse P11 is applied to the input port of the first splitter 230₁. In addition, FIG. 3I illustrates a timing diagram 310-9 which further shows the output current waveform I_{Q} for the period t₈ to t₉, where the output current I_{Q} remains at I_{Q}=0.

Next, FIG. 3J illustrates an operating state 300-10 of the superconducting square pulse waveform generator 200 at time t₁₀, where the first splitter 230₁ outputs a first SFQ pulse P12a and a second SFQ pulse, in response to the SFQ pulse P11 applied to the input port thereof, after a fixed propagation delay time. The first SFQ pulse P12a is applied to the input port of the third JTL 220₃, and the second SFQ pulse P12b is applied to the input port of the fourth JTL 220₄. In addition, FIG. 3J illustrates a timing diagram 310-10 which further shows the output current waveform I_{Q} for the period t₉ to t₁₀, where the output current I_{Q} remains at I_{Q}=0.

Next, FIG. 3K illustrates an operating state 300-11 of the superconducting square pulse waveform generator 200 at time t₁₁, where (i) the third JTL 220₃ outputs an SFQ pulse P13, in response to the SFQ pulse P12a applied to the input port thereof, after a fixed propagation delay time, and (ii) the fourth JTL 220₄ outputs an SFQ pulse P14, in response to the SFQ pulse P12b applied to the input port thereof, after a fixed propagation delay time. The SFQ pulse P13 is applied to the input port of the second splitter 230₂. The SFQ pulse P14 is applied to the superconducting inductor 202. In addition, FIG. 3K illustrates a timing diagram 310-11 which further shows the output current waveform I_{Q} for the period t₁₀ to t₁₁, where the output current I_{Q} remains at I_{Q}=0.

Next, FIG. 3L illustrates an operating state 300-12 of the superconducting square pulse waveform generator 200 at time t₁₂, where the second splitter 230₂ outputs a first SFQ pulse P15a and a second SFQ pulse P15b, in response to the SFQ pulse P13 applied to the input port thereof, after a fixed propagation delay time. The first SFQ pulse P15a is applied to the input port of the first delay JTL 240₁, and the second SFQ pulse P15b is applied to the input port of the second delay JTL 240₂. In addition, FIG. 3L illustrates a timing diagram 310-12 which further shows the output current waveform I_{Q} for the period t₁₁ to t₁₂, where the output current I_{Q} abruptly increases (just after t₁₁) to

$${I}_{Q} = \frac{{Φ}_{0}}{{L}_{Q}} .$$

The output current I_{Q} is generated as a result of applying the SFQ pulse P14 (FIG. 3K), which is output from the fourth JTL 220₄, to the superconducting inductor 202 with the quantizing inductance L_{Q}.

Next, FIG. 3M illustrates an operating state 300-13 of the superconducting square pulse waveform generator 200 at time t₁₃, where (i) the second delay JTL 240₂ outputs an SFQ pulse P16, in response to the SFQ pulse P15b applied to the input port thereof, after the selectively tuned propagation delay time of the second delay JTL 240₂, and (ii) the first delay JTL 240₁ outputs an SFQ pulse P17, in response to the SFQ pulse P15a applied to the input port thereof, after the selectively tuned propagation delay time of the first delay JTL 240₁. The SFQ pulse P16 is applied to the superconducting inductor 202, and the SFQ pulse P17 is applied to the second input port of the confluence buffer 210. In addition, FIG. 3G illustrates a timing diagram 310-13 which further shows the output current waveform I_{Q} for the period t₁₂ to t₁₃, where the output current I_{Q} remains at

$${I}_{Q} = \frac{{Φ}_{0}}{{L}_{Q}}$$

up to time t₁₃.

Next, FIG. 3N illustrates an operating state 300-14 of the superconducting square pulse waveform generator 200 at time t₁₄, where (i) the confluence buffer 210 outputs an SFQ pulse P18 in response to the SFQ pulse P17 applied to the input port thereof, after a fixed propagation delay time, and where (ii) the SFQ pulse P16 (antifluxon), which is output from the second delay JTL 240₂ and injected into the superconducting current loop, causes a negative current

$${I}_{Q}^{-} = - \frac{{Φ}_{0}}{{L}_{Q}}$$

to be generated and now through the superconducting inductor 202 to thereby cancel the positive current

$${I}_{Q}^{+} = \frac{{Φ}_{0}}{{L}_{Q}}$$

flowing through the superconducting inductor 202, resulting in a net current of

$${I}_{Q}^{+} + {I}_{Q}^{-} = 0.$$

In addition, FIG. 3N illustrates a timing diagram 310-14 which further shows the output current waveform I_{Q} for the period t₁₃ to t₁₄, where the output current I_{Q} abruptly decreases (just after t₁₃) to I_{Q}=0, as a result of the SFQ pulse P16 that is output from the second delay JTL 240₂. The timing diagram 310-14 illustrates a square-shaped current pulse having the same pulse width (W) as the previously generated current pulse due primarily to the selectively tuned propagation delay of the second delay JTL 240₂. Moreover, the timing diagram 310-14 illustrates that the square-shaped current pulses have a pulse period T (or pulse-to-pulse spacing) which is due primarily to the selectively tuned propagation delay of the first delay JTL 240₁.

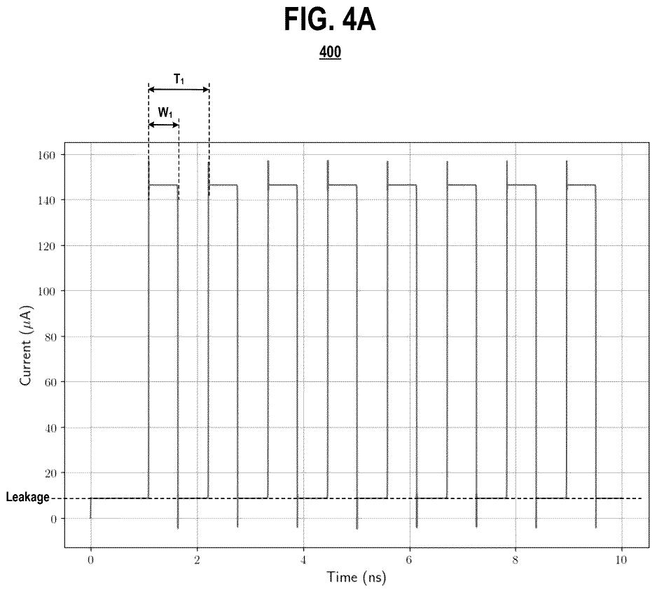

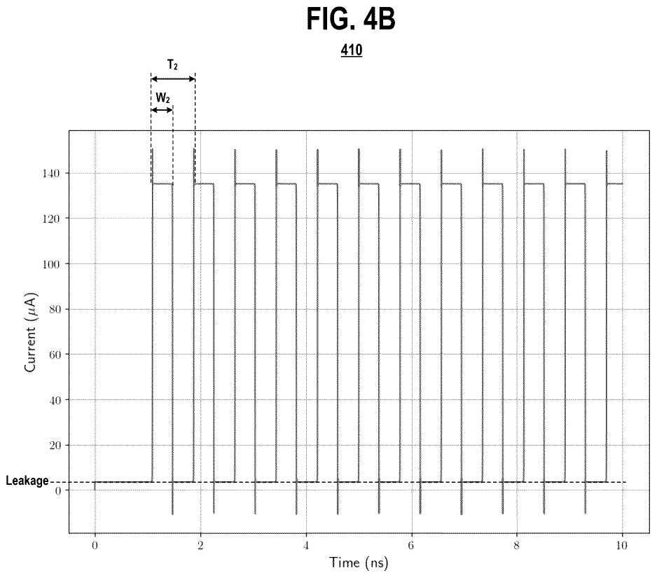

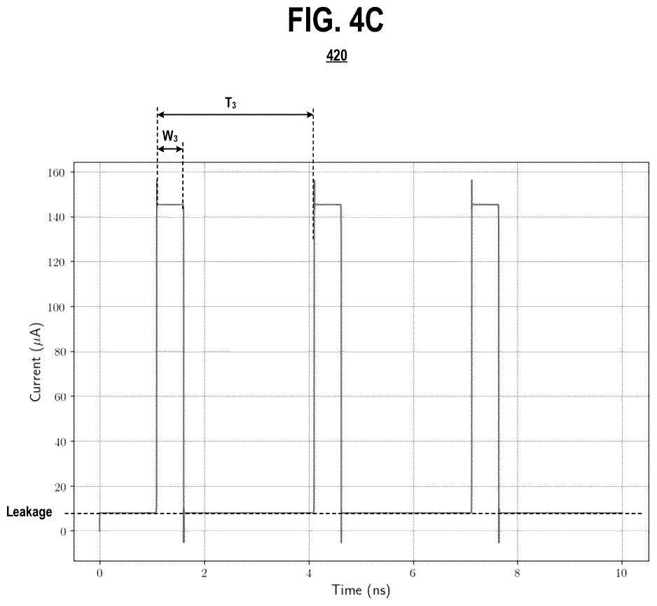

FIGS. 4A, 4B, and 4C illustrate simulated square pulse waveforms which can be generated using a superconducting square pulse waveform generator, according to exemplary embodiments of the disclosure. In particular, 4A, 4B, and 4C illustrate simulated square pulse waveforms that are generated based on a simulated model of a superconducting square pulse waveform generator having an exemplary circuit architecture as shown in FIG. 2, with the superconducting inductor 202 having an inductance of about 8.2 picohenries.

FIG. 4A illustrates a simulated square pulse waveform 400 comprising a sequence of current pulses with a pulse width W₁, a pulse period T₁, and a pulse amplitude of about 150 microamps. The pulse width W₁ is slightly greater than 0.50 nanoseconds, and the pulse period T₁ is approximately 1.125 nanoseconds, which corresponds to a frequency of about 0.90 GHz. The simulated square pulse waveform 400 shows a non-zero offset current of approximately 5 microamps which flows during pulse Off times. The non-zero offset current represents a leakage current that flows through the superconducting inductor 202 as a result of unequal bias currents of the fourth JTL 220₄ and the second delay JTL 240₂, which causes some static leakage current to flow in the positive direction through the superconducting inductor 202. The unequal bias currents is due to the second delay JTL 240₂ being under biased to delay the switching of Josephson junctions thereof and thereby achieve a desired propagation delay through the second delay JTL 240₂.

Next, FIG. 4B illustrates a simulated square pulse waveform 410 comprising a sequence of current pulses with a pulse width W₂, a pulse period T₂, and a pulse amplitude of about 140 microamps. The pulse width W₂ is approximately 0.40 nanoseconds, and the pulse period T₂ is approximately 0.80 nanoseconds, which corresponds to a frequency of about 1.25 GHZ. Again, the simulated square pulse waveform 410 shows a non-zero offset current of approximately 5 microamps, which represents a leakage current that flows through the superconducting inductor 202 during as a result of unequal bias currents of the fourth JTL 220₄ and the second delay JTL 240₂.

It is to be noted that FIGS. 4A and 4B illustrate exemplary simulated square pulse waveforms 400 and 410 having different pulse widths and pulse periods, where W₁>W₂, and T₁>T₂, wherein the different pulse widths and pulse periods can be dynamically adjusted and set simply by utilizing DC control signals, DC_CON1, and DC_CON2, to adjust the respective DC bias currents I_{B1} and I_{B2} that are applied to the first delay JTL 240₁ and the second delay JTL 240₂. As noted above, increasing the bias currents I_{B1} and I_{B2} results in decreasing the propagation delays of the first delay JTL 240₁ and the second delay JTL 240₂ which, in turn, results in decreasing the pulse width and pulse period of the pulses of the square pulse waveform, and thus increasing the frequency of the continuous square pulse waveform. On the other hand, decreasing the bias currents I_{B1} and I_{B2} results in increasing the propagation delays of the first delay JTL 240₁ and the second delay JTL 240₂ which, in turn, results in increasing the pulse width and pulse period of the pulses of the square pulse waveform, and thus decreasing the frequency of the continuous square pulse waveform.

In addition, FIGS. 4A and 4B illustrate exemplary simulated square pulse waveforms 400 and 410 having a duty cycle of approximately 50%. In some embodiments, this can be achieved when the first and second delay JTLs 240₁ and 240₂ comprises nominally identical circuit architectures, and are controlled with a same DC bias current. In other embodiments, the first and second delay JTLs 240₁ and 240₂ are controlled using different DC bias currents (e.g., independent DC current bias sources) to achieve any desired combination of pulse width and pulse period. For example, FIG. 4C illustrates a simulated square pulse waveform 420 comprising a sequence of current pulses with a pulse width W₃, a pulse period T₃, and a pulse amplitude of about 150 microamps. The pulse width W₃ is approximately 0.50 nanoseconds, and the pulse period T₃ is approximately 3.0 nanoseconds, which corresponds to a frequency of about 333.3 MHz. Again, the simulated square pulse waveform 420 shows a non-zero offset current of approximately 5 microamps, which represents a leakage current that flows through the superconducting inductor 202 as a result of unequal bias currents of the fourth JTL 220₄ and the second delay JTL 240₂, which causes some static leakage current to flow in the positive direction through the superconducting inductor 202.

It is to be appreciated that the simulated waveforms of FIGS. 4A, 4B, and 4C demonstrate that SFQ-based superconducting square pulse waveform generator architectures, such as shown in FIG. 2, can be implemented to generate continuous square pulse waveforms with relatively high frequencies (e.g., greater than 1 GHz), and with square pulses having significant fast rise times (e.g., about 1.0 picosecond), which is highly desirable for various application, such as high-speed switching applications.

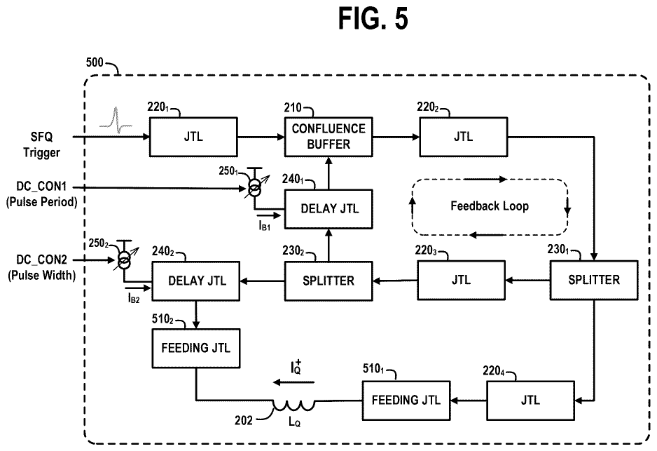

FIG. 5 schematically illustrates a superconducting square pulse waveform generator, according to another exemplary embodiment of the disclosure. In particular, FIG. 5 schematically illustrates a superconducting square pulse waveform generator 500 which is similar in architecture and operation to the superconducting square pulse waveform generator 200 of FIG. 2, except that the superconducting square pulse waveform generator 500 further comprises a first feeding JTL 510₁ and a second feeding JTL 510₂ in the circulating current path to provide larger current sourcing and sinking. As schematically shown in FIG. 5, the first feeding JTL 510₁ is coupled to and between the fourth JTL 220₄ and the first terminal of the superconducting inductor 202, and the second feeding JTL 510₂ is coupled to and between the second delay JTL 240₂ and the second terminal of the superconducting inductor 202. In the exemplary embodiment of FIG. 5, the fourth JTL 220₄, the superconducting inductor 202, the second delay JTL 240₂, and the first and second feeding JTLs 510₁ and 510₂ collectively form a second superconducting sub-circuit which comprises a superconducting loop.

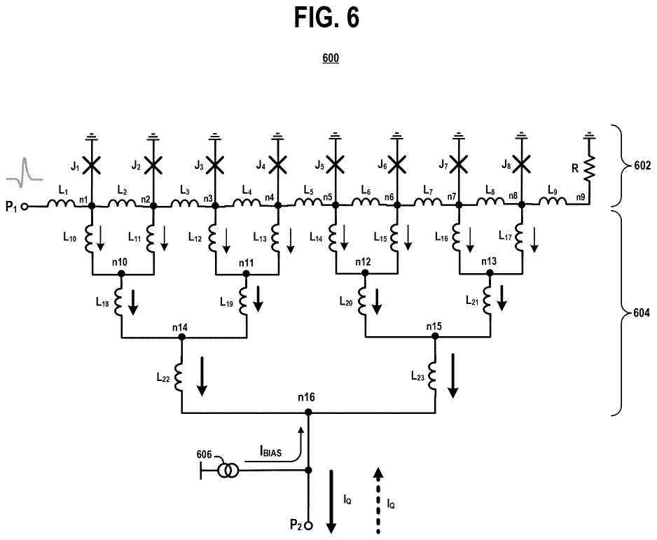

In an exemplary embodiment where the fourth JTL 220₄ and the second delay JTL 240₂ each comprise a two-stage JTL circuit structure (e.g., FIG. 9), current sourcing (and sinking) is limited since all current is sourced from a single Josephson junction, which places limitations on the superconducting inductor 202 (e.g., value of quantizing inductance). In this regard, while the exemplary superconducting square pulse waveform generator 200 of FIG. 2 can source and sink current in the circulating current path up to about 160 microamps (as shown by the pulse amplitudes of the simulated waveforms of FIGS. 4A-4C), in certain instances, it is desirable to generate square pulse waveforms with pulse amplitudes that are greater than 160 microamps, which may not be possible using only the fourth JTL 220₄ and the second delay JTL in the circulating current path for sourcing and sinking the circulating loop current. On the other hand, the implementation of the first feeding JTL 510₁ and the second feeding JTL 510₂ in the circulating current path of FIG. 5 enables larger current sourcing and sinking and, thus, the generation of square pulse waveforms with relatively large current pulse amplitudes (e.g., 160 microamps or greater). An exemplary circuit architecture for implementing the first feeding JTL 510₁ and the second feeding JTL 510₂ will be discussed below in conjunction with FIG. 6.

It is to be further noted that implementation of the first and second feeding JTLs 510₁ and 510₂ in the circulating current path of the superconducting square pulse waveform generator 500 services to eliminate or otherwise significantly reduce the leakage current through the superconducting inductor 202, which results in the DC current offsets of the exemplary square pulse waveforms shown in FIGS. 4A-4C. Indeed, despite the difference in the biasing of the second delay JTL 240₂ (which is under-biased) and the fourth JTL 220₄ which leads to the small leakage current, the first and second feeding JTLs 510₁ and 510₂ serve to absorb the small leakage current since the fourth JTL 220₄ and the second delay JTL 240₂ are loaded by the first feeding JTL 510₁ and the second feeding JTL 510₂, which helps to eliminate or significantly reduce the amount of leakage current which flows through the superconducting inductor 202.

FIG. 6 schematically illustrates a feeding JTL circuit which can be implemented in a superconducting square pulse waveform generator, according to an exemplary embodiment of the disclosure. In some embodiments, FIG. 6 schematically illustrates an exemplary architecture of a feeding JTL 600 which can be utilized to implement the first feeding JTL 510₁ and the second feeding JTL 510₂ of the superconducting square pulse waveform generator 500 shown in FIG. 5. The feeding JTL 600 comprises a first port P1, a second port P2, a multi-stage Josephson transmission line 602, a balanced inductor H-tree circuit 604, and a DC bias current source 606.

The first port P1 is configured to receive an SFQ pulse. For example, assuming that the feeding JTL 600 is used to implement the first feeding JTL 510₁, the first port P₁ would be coupled to an output port of the fourth JTL 220₄ to receive an SFQ pulse, which is output from the fourth JTL 220₄, to generate a positive circulating current in the circulating current path of the superconducting square pulse waveform generator 500. In addition, assuming that the feeding JTL 600 is used to implement the second feeding JTL 510₂, the first port P1 would be coupled to an output port of the second delay JTL 240₂ to receive an SFQ pulse, which is output from the second delay JTL 240₂, to generate a negative circulating current in the circulating current path of the superconducting square pulse waveform generator 500.

The second port P2 is coupled to a terminal of the superconducting inductor 202. As schematically illustrated in FIG. 6, the second port P2 outputs (sources) a current

$${I}_{Q} = \frac{{Φ}_{0}}{{L}_{Q}}$$

in response to the SFQ pulse applied to the input port P1. The current I_{Q} can be (i) a positive current that flows in the circulating current path of the superconducting square pulse waveform generator 500, or (ii) a negative current that flows in the circulating current path to cancel the positive current and thereby generate a current pulse, as disused above. In addition, as explained in further detail below, the second port P2 is configured to sink a current I_{Q} that that flows in the circulating current path of the superconducting square pulse waveform generator 500.

The multi-stage Josephson transmission line 602 comprises a plurality of Josephson junctions J₁, J₂, J₃, J₄, J₅, J₆, J₇, and J₈, and a plurality of superconducting inductors L₁, L₂, L₃, L₄, L₅, L₆, L₇, L₈, and L₉ (which are non-quantizing superconducting inductors), forming an exemplary 8-stage Josephson transmission line, where one end of the multi-stage Josephson transmission line 602 is terminated to a ground node GND via a resistor R. The Josephson junctions J₁, J₂, J₃, J₄, J₅, J₆, J₇, and J₈ are coupled between the ground node GND and respective nodes n1, n2, n3, n4, n5, n6, n7, and n8. In some embodiments, the multi-stage Josephson transmission line 602 is a non-amplifying Josephson transmission line where the Josephson junctions J₁-J₈ have the same operating characteristics, e.g., the Josephson junctions J₁-J₈ have a same critical current I_{C}. The DC bias current source 606 is configured to generate a bias current IBIAS for DC biasing the Josephson junctions J₁-J₈. The bias current IBIAS is distributed to Josephson junctions J₁-J₈ over the balanced inductor H-tree circuit 604.

The balanced inductor H-tree circuit 604 comprises a current distribution network that is configured to evenly distribute bias current IBIAS and the circulating current I_{Q}. For example, the balanced inductor H-tree circuit 604 is used to bias the multi-stage Josephson transmission line 602. The balanced inductor H-tree circuit 604 comprises a plurality of superconducting inductors L₁₀, L₁₁, L₁₂, L₁₃, L₁₄, L₁₅, L₁₆, L₁₇, L₁₈, L₁₉, L₂₀, L₂₁, L₂₂, and L₂₃, which are arranged in an H-tree configuration having branch nodes n10, n11, n12, n13, n14, n15, and n16. The node n16 (e.g., root node of H-tree) is coupled to the second port P2.

The superconducting inductors L₁₀-L₂₃ of the balanced inductor H-tree circuit have inductances that are selected to cause the bias current IBIAS, which is input to the root node n16 to be divided and equally distributed to each of the Josephson junctions J₁-J₈ so that each Josephson junction J₁-J₈ is biased with the same, or substantially the same, bias current. In particular, with the exemplary balanced inductor H-tree circuit 604 shown in FIG. 6, the bias current IBIAS is equally split at node n16 where about one-half (½) of the input static bias current flows to each of the nodes N15 and N14. The bias currents at nodes n14 and n15 are then equally split again, and the bias currents at nodes n10, n11, n12, and n13 are equally split again, such that each Josephson junction J₁-J₈ receives about one-eighth (⅛) of the bias current IBIAS that is input to the node n16.

Furthermore, when second port P2 of the feeding JTL 600 sinks a circulating current I_{Q} that is sourced from another circuit, the balanced inductor H-tree circuit 604 will evenly divide and distribute the current I_{Q} to each Josephson junction J₁-J₈. With this circuit configuration, the Josephson junctions J₁-J₈ can absorb and shunt the equally divided current I_{Q} to the ground node GND without causing the Josephson junctions J₁-J₈ to switch as a result of too high a current flowing through a Josephson junction (i.e., above the critical current of the Josephson junction). Without the balanced inductor H-tree circuit 604, the incoming current I_{Q} may not be evenly divided, and a Josephson junction that receives a current that is greater than its critical current may undesirably switch.

FIG. 6 schematically illustrates an exemplary mode of operation of the feeding JTL 600 in which the feeding JTL sources a current I_{Q} in response to a single SFQ pulse (e.g., single fluxon) that is applied to the first port P1. The input SFQ pulse applied to the first port P1 causes the switching, in succession, of the Josephson junctions J₁, J₂, J₃, J₄, J₅, J₆, J₇, and J₈, which causes some portion of the sourcing current I_{Q} to be injected into the balanced inductor H-tree circuit 604 each time one of the Josephson junctions J₁, J₂, J₃, J₄, J₅, J₆, J₇, and J₈ switches. As is known in the art, a Josephson junction will switch to a resistive state when the current flow through the Josephson junction exceeds the critical current I_{C} of the Josephson junction. The critical current I_{C} of a Josephson junction denotes a maximum amount of current that can coherently flow through the Josephson junction, while exhibiting no resistive dissipation, wherein the Josephson junction operates as a nonlinear superconducting inductor when the amount of superconducting current flowing through the Josephson junction is less than the critical current I_{C}. However, when the current flow through the Josephson junction exceeds its critical current I_{C}, the Josephson junction temporarily transitions to a resistive state, which causes a finite voltage to develop across the Josephson junction.

In the context of the exemplary feeding JTL 600 shown in FIG. 6, the input SFQ pulse applied to the first port P1 generates a circulating current which causes the Josephson junction J₁ to be temporarily driven above its critical current which, in turn, causes the Josephson junction J₁ to switch and generate an SFQ pulse at the node n1. The SFQ pulse at the node n1 causes some current to be injected from node n1 into the balanced inductor H-tree circuit 604. The SFQ pulse at node n1 generates a circulating current which causes the Josephson junction J₂ to be temporarily driven above its critical current which, in turn, causes the Josephson junction J₂ to switch and generate an SFQ pulse at the node n2. The SFQ pulse generated at the node n2 causes some current to be injected from node n2 into the balanced inductor H-tree circuit 604.

This switching process is sequentially repeated along the multi-stage Josephson transmission line 602, wherein the multi-stage Josephson transmission line 602 essentially operates as an SFQ pulse repeater, wherein the input SFQ pulse is actively regenerated at each of the nodes n1, n2, n3, n4, n5, n6, n7, and n8 in succession after a short propagation delay, where a final SFQ pulse at the node n9 is dissipated to ground through the resistor R. As noted above, the superconducting inductors L₁-L₉ of the multi-stage Josephson transmission line 602 are designed to have relatively low inductance values such that the superconducting inductors L₁-L₉ are non-quantizing inductors to ensure that (i) no magnetic flux quanta can be stored/trapped between the JTL stages and that (ii) the input SFQ pulse results in a relatively high magnitude circulating currents to cause the successive switching of the Josephson junctions J₁-J₈.

As illustrated in FIG. 6, the currents (schematically represented by arrows), which are injected from the nodes n1, n2, n3, n4, n5, n6, n7, and n8 into the balanced inductor H-tree circuit 604, are combined at node n16 to generate a total current

$${I}_{Q} = \frac{{Φ}_{0}}{{L}_{Q}}$$

which is output from the second port P₂, in response to the single SFQ pulse applied to the first port P₁. The feeding JTL 600 will source a total current of

$${I}_{Q} = \frac{{Φ}_{0}}{{L}_{Q}}$$

in response to single SFQ pulse applied to the first port P₁ thereof, where each Josephson junction J₁-J₈ provides ⅛ of the total current

$${I}_{Q} = \frac{{Φ}_{0}}{{L}_{Q}}$$

that is sourced by the feeding JTL 600. It is to be noted that while FIG. 6 schematically illustrates an exemplary mode of operation where the feeding JTL 600 sources a total current I_{Q} in response to a single SFQ pulse, the feeding JTL 600 is also configured to operate as a current sink to sink a current I_{Q} which is input to the second port P2, as schematically represented as a dashed arrow. As noted above, when second port P2 of the feeding JTL 600 sinks a circulating current I_{Q} that is sourced from another circuit, the balanced inductor H-tree circuit 604 will evenly divide and distribute the current I_{Q} to each Josephson junction J₁-J₈, such that each Josephson junction J₁-J₈ sinks ⅛ of the total current I_{Q} to ground.

It is to be noted that while FIG. 6 illustrates an exemplary embodiment of a feeding JTL which comprises four (4) stages comprising a total of eight (8) Josephson junction, in other embodiments, a feeding JTL can be implemented with any suitable number n of Josephson junctions, wherein for a given quantizing inductance L_{Q}, each of the n Josephson junction will provide 1/n of the total current

$${I}_{Q} = \frac{{Φ}_{0}}{{L}_{Q}} ,$$

in response to a single input SFQ pulse. The number n of Josephson junctions for implementing a feeding JTL can be chosen depending on, e.g., a desired maximum current I_{Q} that the feeding JTL will need to source or sink for a given application.

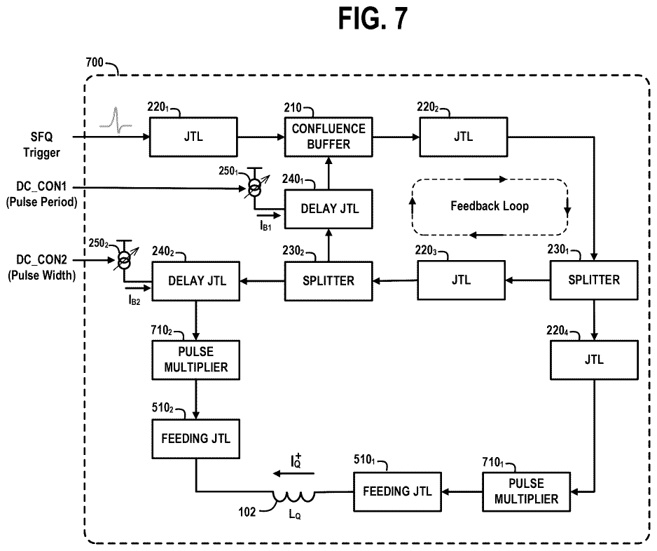

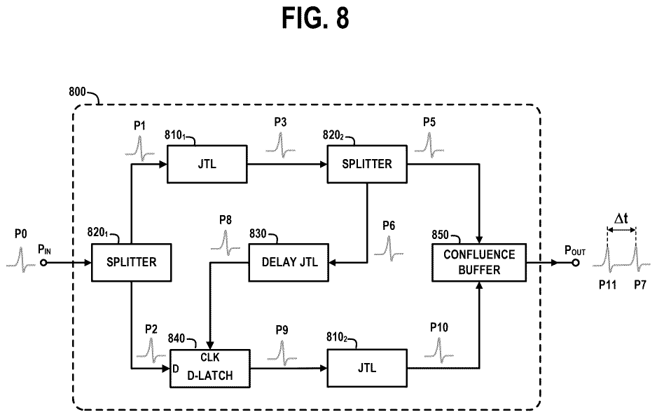

FIG. 7 schematically illustrates a superconducting square pulse waveform generator, according to another exemplary embodiment of the disclosure. In particular, FIG. 7 schematically illustrates a superconducting square pulse waveform generator 700 which is similar in architecture and operation to the superconducting square pulse waveform generators 200 and 500 of FIGS. 2 and 5, except that the superconducting square pulse waveform generator 700 further comprises a first pulse multiplier 710₁ and a second pulse multiplier 710₂ in the circulating current path which, as explained in further detail blow, enable a larger current to be generated in the circulating current path. In the exemplary embodiment of FIG. 7, the fourth JTL 220₄, the superconducting inductor 202, the second delay JTL 240₂, the first and second feeding JTLs 510₁ and 510₂, and the first and second pulse multipliers 710₁ and 710₂ collectively form a second superconducting sub-circuit which comprises a superconducting loop. An exemplary circuit architecture for implementing the first pulse multiplier 710₁ and the second pulse multiplier 710₂ will be discussed below in conjunction with FIG. 8.

As schematically shown in FIG. 7, the first pulse multiplier 710₁ is coupled to and between the fourth JTL 220₄ and the first feeding JTL 510₁, and the second pulse multiplier 710₂ is coupled to and between the second delay JTL 240₂ and the second feeding JTL 510₂. The first pulse multiplier 710₁ is configured to generate and output m SFQ pulses to the first feeding JTL 510₁, in response to a single SFQ pulse (single Set pulse) which is output from the fourth JTL 220₄ and applied to first pulse multiplier 710₁. Similarly, the second pulse multiplier 710₂ is configured to generate and output m SFQ pulses to the second feeding JTL 510₂, in response to a single SFQ pulse (single Reset pulse) which is output from the second delay JTL 240₂ and applied to second pulse multiplier 710₂.

Moreover, in response to the m SFQ pulses output from the first pulse multiplier 710₁, the first feeding JTL 510₁ generates a total positive current

$${I}_{Q}^{+} = m * \frac{{Φ}_{0}}{{L}_{Q}} ,$$

where for each SFQ pulse (of the m SFQ pulses) that is input to the first feeding JTL 510₁, the first feeding JTL 510₁ generates a fraction 1/m of the total positive current

$${I}_{Q}^{+} = m * \frac{{Φ}_{0}}{{L}_{Q}} .$$

Similarly, in response to the m SFQ pulses output from the second pulse multiplier 710₂, the second feeding JTL 510₂ generates a total negative current

$${I}_{Q}^{-} = - m * \frac{{Φ}_{0}}{{L}_{Q}} ,$$

where for each SFQ pulse (of the m SFQ pulses) that is input to the second feeding JTL 510₂, the second feeding JTL 510₂ generates a faction 1/m of the total negative current

$${I}_{Q}^{-} = - m * \frac{{Φ}_{0}}{{L}_{Q}} .$$

In this exemplary configuration, the first feeding JTL 510₁ is configured to generate and source the positive current

$${I}_{Q}^{+} = m * \frac{{Φ}_{0}}{{L}_{Q}} ,$$

and the second feeding JTL 510₂ is configured to generate and source the negative current

$${I}_{Q}^{-} = - m * \frac{{Φ}_{0}}{{L}_{Q}} ,$$

to thereby cancel the positive current

$${I}_{Q}^{+} = - m * \frac{{Φ}_{0}}{{L}_{Q}} ,$$

and generate a square-shaped current pulse with a magnitude of

$${I}_{Q} = - m * \frac{{Φ}_{0}}{{L}_{Q}} ,$$

such as discussed above.

The exemplary superconducting square pulse waveform generator 700 of FIG. 7 can be implemented for applications where, e.g., a relatively large quantizing inductance L_{Q} is needed to obtain a relatively large mutual inductance and magnetic coupling between the superconducting inductor 202 and a given quantum device such as a secondary inductor of a given quantum device or quantum circuit (e.g., FIG. 1A), or a DC-SQUID of a given quantum device or quantum circuit (e.g., FIG. 1B). In such instances, increasing the magnitude of the quantizing inductance L_{Q}, together with increasing the number of SFQ pulses to achieve a larger current I_{Q} (e.g., 200 microamps or higher), can provide a desired amount of mutual coupling and magnetic flux coupling/biasing of a target DUT.

FIG. 8 schematically illustrates an SFQ pulse multiplier which can be implemented in a superconducting square pulse waveform generator, according to an exemplary embodiment of the disclosure. In some embodiments, FIG. 8 schematically illustrates an exemplary architecture of an SFQ pulse multiplier 800 which can be utilized to implement the first pulse multiplier 710₁ and the second pulse multiplier 710₂ of the superconducting square pulse waveform generator 700 shown in FIG. 7. The SFQ pulse multiplier 800 comprises an input port PIN, an output port POUT, a first JTL 810₁, a second JTL 810₂, a first splitter 820₁, a second splitter 820₂, a delay JTL 830, a D-latch circuit 840, and a confluence buffer 850.

The input port PIN is coupled to an input of the first splitter 820₁. The first splitter 820₁ comprises a first output port that is coupled to an input port of the first JTL 810₁, and a second output port that is coupled to a data input (D) of the D-latch circuit 840. An output port of the first JTL 810₁ is coupled to an input port of the second splitter 820₂. The second splitter 820₂ comprises a first output port that is coupled to a first input port of the confluence buffer 850, and a second output port that is coupled to an input port of the delay JTL 830. An output port of the delay JTL 830 is coupled to a clock CLK input port of the D-latch circuit 840. An output port of the D-latch circuit 840 is coupled to an input port of the second JTL 810₂. An output port of the second JTL 810₂ is coupled to a second input port of the confluence buffer 850. An output port of the confluence buffer 850 is coupled to the output port Pour of the SFQ pulse multiplier 800.

As schematically illustrated in FIG. 8, the SFQ pulse multiplier 800 is configured to receive an input SFQ pulse at the input port PIN thereof, and then output two SFQ pulses from the output port POUT, in response to the input SFQ pulse. More specifically, an SFQ pulse P0 at the input port PIN is applied to the input port of the first splitter 820₁, and the first splitter 820₁ outputs (i) a first SFQ pulse P1 which is applied to the input port of the first JTL 810₁ and (ii) a second SFQ pulse P2 which is applied to the data D input port of the D-latch circuit 840 where the second SFQ pulse P2 is temporarily stored as a circulating supercurrent.

In response to the input SFQ pulse P1, the first JTL 810₁ outputs an SFQ pulse P3 which is applied to the input port of the second splitter 820₂. In response to the input SFQ pulse P3, the second splitter 820₂ outputs (i) a first SFQ pulse P5 which is applied to the first input port of the confluence buffer 850, and (ii) a second SFQ pulse P6 which is applied to the input port of the delay JTL 830. In response to the SFQ pulse P5, the confluence buffer 850 outputs an SFQ pulse P7.

In response to the SFQ pulse P6, the delay JTL 830 outputs an SFQ pulse P8 which is applied to the clock CLK input port of the D-latch circuit 840. In some embodiments, the delay JTL 830 is configured to have a fixed propagation delay time t_{D} in which the SFQ pulse P8 is output from the delay JTL 830 after receiving the SFQ pulse P5. In other embodiments, the delay JTL 830 is configured to have an adjustable propagation delay time t_{D} by, e.g., adjusting the amount of DC bias current applied to the delay JTL 830.

Next, in response to the SFQ pulse P8 applied to the clock CLK input port of the D-latch circuit 840, the second SFQ pulse P2 which is stored in the D-latch circuit 840 as a circulating supercurrent, is released and output as an SFQ pulse P9 that is applied to the input port of the second JTL 810₂. In response to the SFQ pulse P9, the second JTL 810₂ outputs an SFQ pulse P10 which is applied to the second input port of the confluence buffer 850. In response to the SFQ pulse P10, the confluence buffer 850 outputs an SFQ pulse P11. In this regard, FIG. 8 illustrates an exemplary configuration of SFQ pulse multiplier 800 which generates two output SFQ pulses P7 and P11 with a time separation, denoted as Δt, in response to the single input SFQ pulse P0, wherein Δt is based primarily on the propagation delay time t_{D} of the delay JTL 830.

As noted above, the SFQ pulse multiplier 800 can be utilized to implement the first pulse multiplier 710₁ and the second pulse multiplier 710₂ of the superconducting square pulse waveform generator 700 shown in FIG. 7. In this instance, the first pulse multiplier 710₁ would output two SFQ pulses (m=2) in response to a single SFQ pulse output from the fourth JTL 220₄, and in response to the m=2 SFQ pulses output from the first pulse multiplier 710₁, the first feeding JTL 510₁ would generate a total positive current

$${I}_{Q}^{+} = - 2 * \frac{{Φ}_{0}}{{L}_{Q}} .$$

Similarly, the second pulse multiplier 710₂ would output two SFQ pulses (m=2) in response to a single SFQ pulse output from the second delay JTL 240₂, and in response to the m=2 SFQ pulses output from the second pulse multiplier 710₂, the second feeding JTL 510₂ would generate a total negative current

$${I}_{Q}^{-} = - 2 * \frac{{Φ}_{0}}{{L}_{Q}} .$$

In other embodiments, the achieve even higher currents, the first pulse multiplier 710₁ and the second pulse multiplier 710₂ can each be configured with multiple (N) instances of the SFQ pulse multiplier 800 which are cascaded to generate a greater number m of SFQ pulses (m=2N) that are input to the first and second feeding JTLs 510₁ and 510₂, but at the cost of increasing the rise time of the square wave current pulses that are generated by the superconducting square pulse waveform generator 700.

It is to be appreciated that there are various advantages associated with the exemplary superconducting square pulse waveform generators as described herein. For example, the superconducting square pulse waveform generators are configured to generate continuous square pulse waveforms in response to a single SFQ trigger pulse, without the need for continuous external driving. In addition, the superconducting square pulse waveform generators can be configured to operate with fixed external bias currents or tunable external bias currents. With fixed external bias currents, a superconducting square pulse waveform generator would freely oscillate with a fixed pulse period and a fixed pulse width, which care set by delay length of, e.g., the delay JTL circuits (e.g., a delay length physically set by a given number of Josephson junctions in the delay JTL circuits). With tunable external bias currents, a superconducting square pulse waveform generator would freely oscillate with a pulse period and a pulse width set by in situ tuning of the external bias currents applied to the delay JTL circuits, as discussed above. In all exemplary embodiments, a superconducting square pulse waveform generator can be turned off by simply turning off the external bias currents to terminate the self-oscillation operation.

Moreover, the exemplary superconducting square pulse waveform generators as described herein enable the generation of high-speed, free-running square pulse signals in a low power and low temperature environment using an entirely DC biased circuit, which removes the thermal, clocking, and power constraints of high-bandwidth wires in cryogenic environments. Indeed, the exemplary superconducting square pulse waveform generators have the ability to generate high-speed or low-speed speed square waves, as desired, with the application of only DC biases, without the need for continuous RF signals. The exemplary superconducting square pulse waveform generators provide a pathway for generating baseband control pulses in an entirely DC biased architecture, thereby lowering cost per control channel (e.g., low RF control wiring overhead) and lowering thermal overhead, while providing very small footprint circuit architectures for generating square pulse waveforms in a cryogenic environment.

The exemplary superconducting square pulse waveform generators as disclosed herein are implemented using various circuit blocks including JTLs, delay JTLs, confluence buffers, SFQ splitters, etc. For example, FIG. 9 schematically illustrates a JTL 900 which can be implemented in a superconducting square pulse waveform generator, according to an exemplary embodiment of the disclosure. The JTL 900 comprises an input port PIN, an output port POUT, a DC bias circuit 902, superconducting inductors L₁, L₂, L₃, and L₄, and Josephson junctions J₁ and J₂. The JTL 900 comprises a multi-stage JTL buffer circuit comprising a first stage which comprises the first Josephson junction J₁ and the superconducting (non-quantizing) inductor L₂, and a second stage which comprises the second Josephson junction J₂ and the superconducting (non-quantizing) inductor L₃.

The DC bias circuit 902 is a current bias source that is connected to node n (bias current injection node) between superconducting inductors L₂, and L₃. The node np is an output node of the first JTL stage and an input node of the second JTL stage. While the DC bias circuit 902 is generically depicted in FIG. 9, it is to be understood that the DC bias circuit 902 can be implemented using a resistor for an RSFQ bias circuit or implemented using an ERSFQ bias circuit, as is known in the art.

The superconducting inductors L₁, L₂, L₃, and L₄ are designed to have relatively low inductance values such that the superconducting inductors L₁, L₂, L₃, and L₄ are non-quantizing inductors to ensure that (i) no magnetic flux quanta can be stored/trapped between the JTL stages and that (ii) an input SFQ pulse 901-1 results in a relatively high magnitude circulating current to cause the successive switching of the Josephson junctions J₁ and J₂. As shown in FIG. 9, the input SFQ pulse 901-1 applied to the input port PIN generates a circulating current which causes the first Josephson junction J₁ to be temporarily driven above its critical current I_{C} which, in turn, causes the Josephson junction J₁ to switch and generate an SFQ pulse at node n1. The SFQ pulse at node n1 generates a circulating current which causes the second Josephson junction J₂ to be temporarily driven above its critical current I_{C} which, in turn, causes the second Josephson junction J₂ to switch and generate an SFQ pulse at node n2, which results in an SFQ pulse 901-2 at the output port Pour. The JTL 900 essentially operates as an SFQ pulse repeater, wherein the input SFQ pulse 901-1 is actively regenerated by each Josephson junction J₁ and J₂ at each node n1 and n2, in succession, after a short propagation delay.

In the exemplary configuration, the first and second JTL stages are both powered by the same DC bias circuit 902. In particular, the DC bias circuit 902 is configured to generate a bias current IBB which is injected into node n_{B}, wherein the bias current IBB divides to provide a first bias current I_{B1} to bias the first Josephson junction J₁, and a second bias current I_{B2} to bias the second Josephson junction J₂. In this configuration, the superconducting inductors L₂ and L₃ form an inductive current divider circuit which is configured to divide the bias current IBB into the first and second bias currents I_{B1} and I_{B2} according to an inductance ratio, between the inductance of the superconducting inductor L₂ in series with the Josephson junction J₁, and the inductance of the superconducting inductor L₃ in series with the Josephson junction J₂. In some embodiments, where L₂ and L₃ have the same or substantially the same inductance, the first and second bias currents I_{B1} and I_{B2} will be substantially the same.

In some embodiments, the first and second delay JTLs 240₁ and 240₂ of the exemplary superconducting square pulse waveform generators 200, 500, 700 (FIGS. 2, 5, and 7) are implemented using the exemplary architecture of the JTL 900 shown in FIG. 9, but where the DC bias circuit 902 would be a variable current source that is configured to generate a variable bias current IBB to adjust the biassing (e.g., under biasing) of Josephson junctions J₁ and J₂ to tune the propagation delay of the SFQ pulse through the JTL 900. As noted above, the propagation delay of the first delay JTL 240₁ can be adjusted to tune the pulse period of a square pulse waveform, and the propagation delay of the second delay JTL 240₂ can be adjusted to tune the pulse width of a square pulse waveform.

Next, FIG. 10 schematically illustrates an SFQ pulse splitter which can be implemented in a superconducting square pulse waveform generator, according to an exemplary embodiment of the disclosure. In particular, FIG. 10 schematically illustrates an SFQ pulse splitter 1000 which comprises an input port PIN, a first output port P_{OUT1}, a second output port P_{OUT2}, a plurality of inductors L₁, L₂, L₃, L₄, L₅, and L₆, and a plurality of Josephson junctions J₁, J₂, and J₃. A plurality of DC bias current sources are implemented to generate bias currents I_{B1}, I_{B2}, and I_{B3} for biasing the Josephson junctions J₁, J₂, and J₃ as needed for proper operation of the SFQ pulse splitter 1000.

In operation, when an SFQ pulse arrives at the input port PIN, the SFQ pulse causes the Josephson junction J₁ to be temporarily driven above its critical current I_{C} which, in turn, causes the Josephson junction J₁ to switch to a voltage state and generate an SFQ pulse at node n1. The SFQ pulse at node n1 propagates through the inductor L₂ to a branch node n_{b}, wherein the SFQ pulse at the node n_{b} causes both of the Josephson junctions J₂ and J₃ (in separate output branches) to concurrently switch into a voltage state. The concurrent switching of the Josephson junctions J₂ and J₃ causes an SFQ pulse to be generated at node n2 and at node n3, which propagate to the respective first and second output ports P_{OUT1} and P_{OUT2}, wherein SFQ pulses are concurrently output from P_{OUT1} and P_{OUT2}. It is to be noted that the critical currents of the Josephson junctions J₁, J₂, and J₃ are designed in a way that allows the switching of the Josephson junction J₁ to drive the concurrent switching of the Josephson junctions J₁ and J₂, as is readily understood by those of ordinary skill in the art.

Next, FIG. 11 schematically illustrates a confluence buffer which can be implemented in a superconducting square pulse waveform generator, according to an exemplary embodiment of the disclosure. In particular, FIG. 11 schematically illustrates a confluence buffer 1100 which comprises a first input port P_{IN1}, a second input port P_{IN2}, an output port POUT, a plurality of inductors L₁, L₂, L₃, L₄, L₅, and L₆, and a plurality of Josephson junctions J₁, J₂, J₃, J₄, and J₅. A plurality of DC bias current sources are implemented to generate bias currents I_{B1}, I_{B2}, I_{B3}, and I_{B4} for biasing the Josephson junctions J₁, J₂, J₃, J₄, and J₅ as needed for proper operation of the confluence buffer 1100.

In operation, when an SFQ pulse arrives at the first input port P_{IN1}, the SFQ pulse causes the Josephson junction J₁ to be temporarily driven above its critical current I_{C} which, in turn, causes the Josephson junction J₁ to switch to a voltage state and generate an SFQ pulse at node n1. The Josephson junction J₂ does not switch and remains in the superconducting state, so that the SFQ pulse generated across J₁ at node n₁ propagates to node n2 and is applied to the inductor L₅. The resulting pulse through L₅ causes the Josephson junction J₅ to switch to a voltage state, whereby an SFQ pulse appears at node n4 which propagates to output port POUT. In addition, the Josephson junction J₄ switches so that the SFQ pulse does not back propagate to the second input port P_{IN2}. Therefore, an SFQ pulse at the first input port P_{IN1} causes the Josephson junctions J₁, J₄, and J₅ to sequentially switch in a way that essentially transfers the SFQ pulse at the first input port P_{IN1} to the output port POUT, while preventing an SFQ pulse from being generated at the second input port P_{IN2}.

Similarly, when an SFQ pulse arrives at the second input port P_{IN2}, the SFQ pulse causes the Josephson junction J₃ to be temporarily driven above its critical current I_{C} which, in turn, causes the Josephson junction J₃ to switch to a voltage state and generate an SFQ pulse at node n3. The Josephson junction J₄ does not switch and remains in the superconducting state, so that the SFQ pulse generated across J₃ at node n3 propagates to node n2 and is applied to the inductor L₅. The resulting pulse through L₅ causes the Josephson junction J₅ to switch to a voltage state, whereby an SFQ pulse appears at node n4 which propagates to the output port Pour. In addition, the Josephson junction J₂ switches so that the SFQ pulse does not back propagate to the first input port P_{IN1}. Therefore, an SFQ pulse at the second input port P_{IN2} causes the Josephson junctions J₃, J₂, and J₅ to sequentially switch in a way that essentially transfers the SFQ pulse at the second input port P_{IN2} to the output port POUT, while preventing an SFQ pulse from being generated at the first input port P_{IN1}.

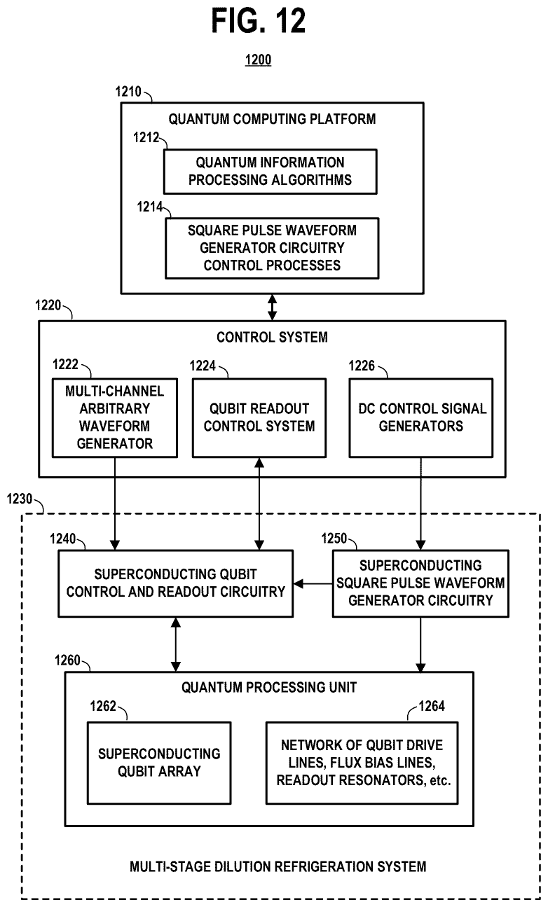

FIG. 12 schematically illustrates a quantum computing system which comprises superconducting square pulse waveform generator circuitry, according to an exemplary embodiment of the disclosure. In particular, FIG. 12 schematically illustrates a quantum computing system 1200 which comprises a quantum computing platform 1210, a control system 1220, a multi-stage dilution refrigeration system 1230 (or cryostat) within which is disposed various superconducting quantum devices and circuitry including, e.g., superconducting qubit control and readout circuitry 1240, superconducting square pulse waveform generator circuitry 1250, and a quantum processing unit (QPU) 1260. The quantum processing unit 1260 comprises one or more solid-state quantum chips which comprise, e.g., a superconducting qubit array 1262, and a network 1264 of qubit drive lines, coupler flux-bias control lines, qubit readout resonators, and other circuit QED components that may be needed for a given application or quantum system configuration.

In some embodiments, the quantum computing platform 1210 implements a software platform that is configured to program a quantum computer to execute quantum information processing algorithms 1212 which are implemented using, e.g., quantum circuits which define computational routines consisting of coherent quantum operations that are performed on quantum data that is stored in qubits of the superconducting qubit array 1262. Furthermore, in some embodiments, the quantum computing platform 1210 implements software control programs to control the functions and operations of the control system 1220. For example, in some embodiments, the quantum computing platform 1210 executes program code to perform a square pulse waveform generator circuitry control processes 1214.

In some embodiments, the control system 1220 comprises a multi-channel arbitrary waveform generator (AWG) 1222, a qubit readout control system 1224, and DC control signal generators 1226. In some embodiments, the control system 1220 implements electronics that are operated at room temperature (e.g., 300 K). On the other hand, the superconducting qubit control and readout circuitry 1240, the superconducting square pulse waveform generator circuitry 1250, and the quantum processing unit 1260 are disposed at different stages of the multi-stage dilution refrigeration system 1230 which can generate cryogenic temperatures, as needed, to operate the superconducting qubit control and readout circuitry 1240, the superconducting square pulse waveform generator circuitry 1250, and the quantum processing unit 1260 for quantum computing applications.

For example, the quantum processing unit 1260 may be cooled down to near-absolute zero, e.g., 10-15 millikelvin (mK), to allow the superconducting qubits to exhibit quantum behaviors. Moreover, in some embodiments, various quantum components of the superconducting qubit control and readout circuitry 1240 (e.g., isolators, circulators, quantum limited amplifiers, filters, I/Q mixers, etc.), and the superconducting square pulse waveform generator circuitry 1250 may be cooled down to temperatures below 4 K, or below 100 mK, etc. It is to be noted that the superconducting square pulse waveform generator circuitry 1250 can be implemented using the exemplary embodiments and circuit blocks as discussed in conjunction with, e.g., FIGS. 2 and 5-11.

In some embodiments, the superconducting qubit array 1262 comprises a quantum system of superconducting qubits, superconducting qubit couplers, and other components commonly utilized to support quantum processing using qubits. The number of superconducting qubits of the superconducting qubit array 1262 can be on the order of tens, hundreds, thousands, or more, etc. The network 1264 of qubit drive lines, coupler flux bias control lines, and qubit readout resonators, etc., is configured to apply microwave control signals to superconducting qubits and coupler circuitry in the superconducting qubit array 1262 to perform various types of gate operations, e.g., single-gate operations, entanglement gate operations, perform error correction operations, etc., as well as read the quantum states of the superconducting qubits. For example, microwave control pulses can be selectively applied to the qubit drive lines of respective superconducting qubits to change the quantum state of the superconducting qubits (e.g., change the quantum state of a given qubit between the ground state and excited state, or to a superposition state) when executing quantum information processing algorithms.

In some embodiments, the multi-channel AWG 1222 is configured to generate microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 1222 comprises a plurality of AWG channels, where each channel is configured to generate microwave control pulses to control respective superconducting qubits of the superconducting qubit array 1262. In some embodiments, each AWG channel comprises a baseband signal generator (or pulse envelope generator), a digital-to-analog converter (DAC) stage, a filter stage, a modulation stage, an amplitude adjust stage, an impedance matching network, and a phase-locked loop system to generate local oscillator (LO) signals (e.g., quadrature LO signals) for the respective modulation stages of the respective AWG channels.

In some embodiments, the multi-channel AWG 1222 comprises a quadrature AWG system which is configured to process quadrature signals, wherein a quadrature signal comprises an in-phase (I) signal component, and a quadrature-phase (Q) signal component. In each AWG channel the baseband signal generator is configured to generate digital quadrature signals I and Q which represent the input baseband data (e.g., digital I and Q pulse envelopes). The DAC stage for the given AWG channel is configured to convert the digital baseband signals, which are output from the baseband signal generator, to analog I_{Q} baseband signals having desired pulse shapes. The filter stage for the given AWG channel is configured to filter the analog I_{Q} baseband signals to thereby generate filtered analog I_{Q} baseband signals. The modulation stage for the given AWG channel is configured to perform analog I_{Q} signal modulation (e.g., single-sideband (SSB) modulation) by using the analog I_{Q} baseband signals to modulate quadrature LO signals to generate and output an analog RF signal (e.g., a single-sideband modulated RF output signal). The amplitude adjust stage is configured to attenuate or amplify the modulated RF output signal, and the impedance matching network is configured to, e.g., drive qubit control line with the modulated RF output signal.

The qubit readout control system 1224 is configured to generate RF readout control signals, which are applied to readout resonators of superconducting qubits in the superconducting qubit array 1262, to readout the quantum states of the superconducting qubits using a dispersive readout scheme which enables quantum non-demolition measurements of the quantum states of the superconducting qubits. In an exemplary embodiment, the qubit readout control system 1224 receives and processes readout control signals from a control process executing on the quantum computing platform 1210. The qubit readout control system 1224 comprises various components that can operate at room temperature including, e.g., a waveform generator, DAC circuitry, low-pass filter circuitry, I/Q mixers, and LO signal generators, and hardware or software-based discriminators to determine the readout states of the superconducting qubits. Other components of the qubit readout control system 1224 include qubit readout circuitry (e.g., circuit components of superconducting qubit control and readout circuitry 1240) such as readout resonators, Purcell filters, isolator circuits, directional couplers, JTWPA circuit, filters, high-electron-mobility-transistor (HEMT) amplifiers, etc., which operate in a cryogenic temperature environment.

In some embodiments, the superconducting square pulse waveform generator circuitry 1250 is controlled by DC control signals, which are generated and transmitted on control lines from the DC control signal generators 1226 (at room temperature) to the superconducting square pulse waveform generator circuitry 1250. The DC control signal generators 1226 are configured to generate DC bias control signals that are applied to the superconducting square pulse waveform generator circuitry 1250 to controllably set the pulse period and pulse width of square pulse waveforms that are generated by various superconducting square pulse waveform generators of the superconducting square pulse waveform generator circuitry 1250 using exemplary techniques as discussed above. As schematically illustrated in FIG. 12, the square pulse waveforms RF generated by the superconducting square pulse waveform generator circuitry 1250 can be utilized to control quantum devices and circuitry of the superconducting qubit control and readout circuitry 1240 and/or the quantum processing unit 1260.

The quantum computing platform 1210 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 1210 comprises a hardware architecture of processors, memory, etc., which is configured to control the execution of quantum applications, and interface with the control system 1220 to (i) generate digital control signals that are converted to analog microwave control signals by the control system 1220, to control operations of the quantum processing unit 1260 when executing a given quantum application, and (ii) to obtain and process digital signals received from the control system 1220, which represent processing results that are generated as a result of the quantum processing unit 1260 executing various qubit gate operations for a given quantum application.

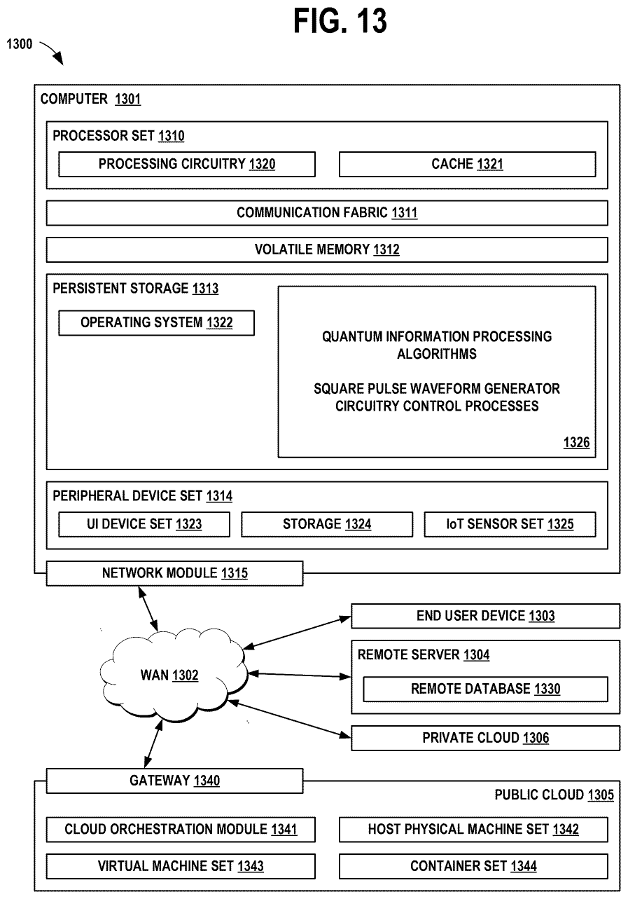

In some exemplary embodiments, the quantum computing platform 1210 of the quantum computing system 1200 may be implemented using any suitable computing system architecture (e.g., as shown in FIG. 13) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 13 schematically illustrates an exemplary architecture of a computing environment 1300 for hosting the quantum computing platform 1210 of FIG. 12, according to an exemplary embodiment of the disclosure. The computing environment 1300 illustrates an example of an environment for the execution of at least some of the computer code (block 1326) involved, for example, in executing quantum information processing algorithms and square pulse waveform generator circuitry control processes. In addition to block 1326, computing environment 1300 includes, for example, computer 1301, wide area network (WAN) 1302, end user device (EUD) 1303, remote server 1304, public cloud 1305, and private cloud 1306. In this embodiment, computer 1301 includes processor set 1310 (including processing circuitry 1320 and cache 1321), communication fabric 1311, volatile memory 1312, persistent storage 1313 (including operating system 1322 and block 1326, as identified above), peripheral device set 1314 (including user interface (UI), device set 1323, storage 1324, and Internet of Things (IoT) sensor set 1325), and network module 1315. Remote server 1304 includes remote database 1330. Public cloud 1305 includes gateway 1340, cloud orchestration module 1341, host physical machine set 1342, virtual machine set 1343, and container set 1344.

Computer 1301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1330. As is well understood in the art of computer technology, and depending upon the technology, performance of a computer-implemented method may be distributed among multiple computers and/or between multiple locations. On the other hand, in this presentation of computing environment 1300, detailed discussion is focused on a single computer, specifically computer 1301, to keep the presentation as simple as possible. Computer 1301 may be located in a cloud, even though it is not shown in a cloud in FIG. 13. On the other hand, computer 1301 is not required to be in a cloud except to any extent as may be affirmatively indicated.

Processor set 1310 includes one, or more, computer processors of any type now known or to be developed in the future. Processing circuitry 1320 may be distributed over multiple packages, for example, multiple, coordinated integrated circuit chips. Processing circuitry 1320 may implement multiple processor threads and/or multiple processor cores. Cache 1321 is memory that is located in the processor chip package(s) and is typically used for data or code that should be available for rapid access by the threads or cores running on processor set 1310. Cache memories are typically organized into multiple levels depending upon relative proximity to the processing circuitry. Alternatively, some, or all, of the cache for the processor set may be located “off chip.” In some computing environments, processor set 1310 may be designed for working with qubits and performing quantum computing.

Computer readable program instructions are typically loaded onto computer 1301 to cause a series of operational steps to be performed by processor set 1310 of computer 1301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1321 and the other storage media discussed below. The program instructions, and associated data, are accessed by processor set 1310 to control and direct performance of the inventive methods. In computing environment 1300, at least some of the instructions for performing the inventive methods may be stored in block 1326 in persistent storage 1313.

Communication fabric 1311 comprises the signal conduction paths that allow the various components of computer 1301 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1312 is any type of volatile memory now known or to be developed in the future. Examples include dynamic type random access memory (RAM) or static type RAM. Typically, the volatile memory is characterized by random access, but this is not required unless affirmatively indicated. In computer 1301, the volatile memory 1312 is located in a single package and is internal to computer 1301, but, alternatively or additionally, the volatile memory may be distributed over multiple packages and/or located externally with respect to computer 1301.

Persistent storage 1313 is any form of non-volatile storage for computers that is now known or to be developed in the future. The non-volatility of this storage means that the stored data is maintained regardless of whether power is being supplied to computer 1301 and/or directly to persistent storage 1313. Persistent storage 1313 may be a read only memory (ROM), but typically at least a portion of the persistent storage allows writing of data, deletion of data and re-writing of data. Some familiar forms of persistent storage include magnetic disks and solid-state storage devices. Operating system 1322 may take several forms, such as various known proprietary operating systems or open source Portable Operating System Interface type operating systems that employ a kernel. The code included in block 1326 typically includes at least some of the computer code involved in performing the inventive methods.

Peripheral device set 1314 includes the set of peripheral devices of computer 1301. Data communication connections between the peripheral devices and the other components of computer 1301 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1323 may include components such as a display screen, speaker, microphone, wearable devices (such as goggles and smart watches), keyboard, mouse, printer, touchpad, game controllers, and haptic devices. Storage 1324 is external storage, such as an external hard drive, or insertable storage, such as an SD card. Storage 1324 may be persistent and/or volatile. In some embodiments, storage 1324 may take the form of a quantum computing storage device for storing data in the form of qubits. In embodiments where computer 1301 is required to have a large amount of storage (for example, where computer 1301 locally stores and manages a large database) then this storage may be provided by peripheral storage devices designed for storing very large amounts of data, such as a storage area network (SAN) that is shared by multiple, geographically distributed computers. IoT sensor set 1325 is made up of sensors that can be used in Internet of Things applications. For example, one sensor may be a thermometer and another sensor may be a motion detector.

Network module 1315 is the collection of computer software, hardware, and firmware that allows computer 1301 to communicate with other computers through WAN 1302. Network module 1315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1315 are performed on the same physical hardware device. In other embodiments (for example, embodiments that utilize software-defined networking (SDN)), the control functions and the forwarding functions of network module 1315 are performed on physically separate devices, such that the control functions manage several different network hardware devices. Computer readable program instructions for performing the inventive methods can typically be downloaded to computer 1301 from an external computer or external storage device through a network adapter card or network interface included in network module 1315.

WAN 1302 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1303 is any computer system that is used and controlled by an end user (for example, a customer of an enterprise that operates computer 1301), and may take any of the forms discussed above in connection with computer 1301. EUD 1303 typically receives helpful and useful data from the operations of computer 1301. For example, in a hypothetical case where computer 1301 is designed to provide a recommendation to an end user, this recommendation would typically be communicated from network module 1315 of computer 1301 through WAN 1302 to EUD 1303. In this way, EUD 1303 can display, or otherwise present, the recommendation to an end user. In some embodiments, EUD 1303 may be a client device, such as thin client, heavy client, mainframe computer, desktop computer and so on.

Remote server 1304 is any computer system that serves at least some data and/or functionality to computer 1301. Remote server 1304 may be controlled and used by the same entity that operates computer 1301. Remote server 1304 represents the machine(s) that collect and store helpful and useful data for use by other computers, such as computer 1301. For example, in a hypothetical case where computer 1301 is designed and programmed to provide a recommendation based on historical data, then this historical data may be provided to computer 1301 from remote database 1330 of remote server 1304.

Public cloud 1305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1305 is performed by the computer hardware and/or software of cloud orchestration module 1341. The computing resources provided by public cloud 1305 are typically implemented by virtual computing environments that run on various computers making up the computers of host physical machine set 1342, which is the universe of physical computers in and/or available to public cloud 1305. The virtual computing environments (VCEs) typically take the form of virtual machines from virtual machine set 1343 and/or containers from container set 1344. It is understood that these VCEs may be stored as images and may be transferred among and between the various physical machine hosts, either as images or after instantiation of the VCE. Cloud orchestration module 1341 manages the transfer and storage of images, deploys new instantiations of VCEs and manages active instantiations of VCE deployments. Gateway 1340 is the collection of computer software, hardware, and firmware that allows public cloud 1305 to communicate through WAN 1302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1306 is similar to public cloud 1305, except that the computing resources are only available for use by a single enterprise. While private cloud 1306 is depicted as being in communication with WAN 1302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1305 and private cloud 1306 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a superconducting square pulse waveform generator which comprises a self-oscillating circuit that is configured to generate a continuous sequence of square current pulses, in response to a single flux quantum (SFQ) pulse applied to an input port of the superconducting square pulse waveform generator;
wherein the self-oscillating circuit is responsive to a first direct current (DC) control signal to tune a pulse period of the continuous sequence of square current pulses, and responsive to a second DC control signal to tune a pulse width of the square current pulses.

2. The device of claim 1, wherein the self-oscillating circuit comprises:
a first superconducting sub-circuit; and
a second superconducting sub-circuit which comprises a quantizing inductor;
wherein the first superconducting sub-circuit is configured to receive the SFQ pulse applied to the input port of the superconducting square pulse waveform generator, and propagate the SFQ pulse around the first superconducting sub-circuit to periodically inject (i) a first SFQ pulse into the second superconducting sub-circuit to cause a first circulating current to flow in a first direction through the quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

3. The device of claim 2, wherein:
the first superconducting sub-circuit comprises a first Josephson transmission line having a tunable propagation delay that is tuned based on the first DC control signal to tune the pulse period of the continuous sequence of square current pulses; and
the second superconducting sub-circuit comprises a second Josephson transmission line having a tunable propagation delay that is adjusted based on the second DC control signal to tune the pulse width of the square current pulses.

4. The device of claim 3, wherein:
the first DC control signal comprises a first DC bias current that is applied to the first Josephson transmission line; and
the second DC control signal comprises a second DC bias current that is applied to the second Josephson transmission line.

5. The device of claim 2, wherein:
the first superconducting sub-circuit comprises a first SFQ pulse splitter, and a second SFQ pulse splitter;
the first SFQ pulse splitter is configured to inject the first SFQ pulse into the second superconducting sub-circuit to cause the first circulating current to flow in the first direction through the quantizing inductor; and
the second SFQ pulse splitter is configured to inject the second SFQ pulse into the second superconducting sub-circuit to cause the second circulating current to flow through the quantizing inductor in the second direction.

6. The device of claim 2, wherein:
the second superconducting sub-circuit comprises a first feeding Josephson transmission line coupled to a first terminal of the quantizing inductor, and a second feeding Josephson transmission line coupled to a second terminal of the quantizing inductor;
the first feeding Josephson transmission line is configured to source the first circulating current and sink the second circulating current; and
the second feeding Josephson transmission line is configured to source the second circulating current and sink the first circulating current.

7. The device of claim 6, wherein:
the second superconducting sub-circuit further comprises a first SFQ pulse multiplier and a second SFQ pulse multiplier;
the first SFQ pulse multiplier is configured to generate a first set of SFQ pulses in response to the first SFQ pulse injected into the second superconducting sub-circuit, and apply the first set of SFQ pulses to the first feeding Josephson transmission line to generate the first circulating current; and
the second SFQ pulse multiplier is configured to generate a second set of SFQ pulses in response to the second SFQ pulse injected into the second superconducting sub-circuit, and apply the second set of SFQ pulses to the second feeding Josephson transmission line to generate the second circulating current.

8. The device of claim 7, wherein the square current pulses have a pulse magnitude which corresponds to
$$m * \frac{{Φ}_{0}}{{L}_{Q}} ,$$
where m denotes a number of SFQ pulses in the first set of SFQ pulses, Φ₀ is the superconducting magnetic flux quantum, and where L_{Q} is an inductance value of the quantizing inductor.

9. The device of claim 2, wherein:
the quantizing inductor is mutually coupled to a superconducting device and generates a magnetic flux bias in response to the square current pulses, which is applied to the superconducting device; and
the superconducting device is one of a superconducting inductor and a superconducting loop comprising Josephson junctions.

10. A device, comprising:
a superconducting square pulse waveform generator which comprises:
a first superconducting sub-circuit; and
a second superconducting sub-circuit which comprises a quantizing inductor;
wherein the first superconducting sub-circuit is configured to receive a single flux quantum (SFQ) pulse applied to an input port of the superconducting square pulse waveform generator, and propagate the SFQ pulse around the first superconducting sub-circuit to periodically inject (i) a first SFQ pulse into the second superconducting sub-circuit to cause a first circulating current to flow in a first direction through the quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

11. The device of claim 10, wherein:
the first superconducting sub-circuit comprises a first Josephson transmission line having a fixed propagation delay which sets a pulse period of a continuous sequence of square current pulses; and
the second superconducting sub-circuit comprises a second Josephson transmission line having fixed propagation delay which sets a pulse width of the square current pulses.

12. The device of claim 10, wherein the square current pulses have a pulse magnitude which is proportional to
$$\frac{{Φ}_{0}}{{L}_{Q}} ,$$
where Φ₀ is the superconducting magnetic flux quantum, and where L_{Q} is an inductance value of the quantizing inductor.

13. The device of claim 10, wherein:
the first superconducting sub-circuit comprises a first SFQ pulse splitter, and a second SFQ pulse splitter;
the first SFQ pulse splitter is configured to inject the first SFQ pulse into the second superconducting sub-circuit to cause the first circulating current to flow in the first direction through the quantizing inductor; and
the second SFQ pulse splitter is configured to inject the second SFQ pulse into the second superconducting sub-circuit to cause the second circulating current to flow through the quantizing inductor in the second direction.

14. The device of claim 10, wherein:
the second superconducting sub-circuit comprises a first feeding Josephson transmission line coupled to a first terminal of the quantizing inductor, and a second feeding Josephson transmission line coupled to a second terminal of the quantizing inductor;
the first feeding Josephson transmission line is configured to source the first circulating current and sink the second circulating current; and
the second feeding Josephson transmission line is configured to source the second circulating current and sink the first circulating current.

15. The device of claim 14, wherein:
the second superconducting sub-circuit further comprises a first SFQ pulse multiplier and a second SFQ pulse multiplier;
the first SFQ pulse multiplier is configured to generate a first set of SFQ pulses in response to the first SFQ pulse injected into the second superconducting sub-circuit, and apply the first set of SFQ pulses to the first feeding Josephson transmission line to generate the first circulating current; and
the second SFQ pulse multiplier is configured to generate a second set of SFQ pulses in response to the second SFQ pulse injected into the second superconducting sub-circuit, and apply the second set of SFQ pulses to the second feeding Josephson transmission line to generate the second circulating current.

16. The device of claim 15, wherein the square current pulses have a pulse magnitude which corresponds to
$$m * \frac{{Φ}_{0}}{{L}_{Q}} ,$$
where m denotes a number of SFQ pulses in the first set of SFQ pulses, Φ₀ is the superconducting magnetic flux quantum, and where L_{Q} is an inductance value of the quantizing inductor.

17. The device of claim 10, wherein:
the quantizing inductor is mutually coupled to a superconducting device and generates a magnetic flux bias in response to the square current pulses, which is applied to the superconducting device; and
the superconducting device is a superconducting inductor or a superconducting loop comprising Josephson junctions.

18. A method, comprising:
receiving, by a superconducting square pulse waveform generator, a single flux quantum (SFQ) pulse; and
generating, by the superconducting square pulse waveform generator, a continuous sequence of square current pulses in response to the SFQ pulse;
wherein generating the continuous sequence of square current pulses comprises propagating the received SFQ pulse around a first superconducting sub-circuit of the superconducting square pulse waveform generator to periodically inject (i) a first SFQ pulse into a second superconducting sub-circuit of the superconducting square pulse waveform generator to cause a first circulating current to flow in a first direction through a quantizing inductor, and (ii) a second SFQ pulse into the second superconducting sub-circuit to cause a second circulating current to flow through the quantizing inductor in a second direction, opposite the first direction, to cancel the first current and thereby generate a square current pulse.

19. The method of claim 18, further comprising:
tuning a propagation delay of a first Josephson transmission line of the first superconducting sub-circuit to tune a pulse period of the continuous sequence of square current pulses; and
tuning a propagation delay of a second Josephson transmission line of the second superconducting sub-circuit to tune a pulse width of the square current pulses.

20. The method of claim 19, wherein the square current pulses have a pulse magnitude which is proportional to
$$\frac{{Φ}_{0}}{{L}_{Q}} ,$$
where Φ₀ is the superconducting magnetic flux quantum, and where L_{Q} is an inductance value of the quantizing inductor.
